(19) United States
(12) Patent Application Publication
(10) Pub. No.: US 2026/0090072 A1
(43) Pub. Date: Mar. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/070,287

(22) Filed: Mar. 4, 2025

(30) Foreign Application Priority Data
Sep. 24, 2024 (JP) 2024-164903

(51) Int. Cl. H10D 84/00; H10D 8/00; H10D 8/60; H10D 30/66; H10D 62/10; H10D 62/13; H10D 62/832; H10D 64/23

(52) U.S. Cl. CPC H10D 84/143; H10D 8/411; H10D 8/60; H10D 30/665; H10D 62/102; H10D 62/153; H10D 62/154; H10D 62/8325; H10D 64/252; H10D 84/146

(57) ABSTRACT

A semiconductor device of embodiments includes an element region and a termination region surrounding the element region. The termination region includes: a silicon carbide layer having a silicon carbide region of a first conductive type, a first silicon carbide region of the second conductive type on the silicon carbide region, and a second silicon carbide region of the second conductive type on the silicon carbide region spaced apart from the first silicon carbide region and surrounding the first silicon carbide region. In the termination region, one contact portion of a wiring layer is connected to the first silicon carbide region, and another contact portion of the wiring layer is connected to the second silicon carbide region. A second conductive type impurity concentration of the first silicon carbide region below the one contact portion is lower than that of the second silicon carbide region below the another contact portion.

### CROSS-REFERENCE TO RELATED APPLICATION

This application is based upon and claims the benefit of priority from Japanese Patent Application No. 2024-164903, filed on Sep. 24, 2024, the entire contents of which are incorporated herein by reference.

### FIELD

Embodiments described herein relate generally to a semiconductor device.

### BACKGROUND

A vertical metal oxide semiconductor field effect transistor (MOSFET) using silicon carbide has a pn junction diode as a built-in diode. For example, a MOSFET is used as a switching element connected to an inductive load. In this case, even when the MOSFET is in an off state, a reflux current can be made to flow by using a pn junction diode.

However, when a reflux current is made to flow by using a pn junction diode that operates in a bipolar manner, a stacking fault grows in a silicon carbide layer due to the recombination energy of the carriers. If the stacking fault grows in the silicon carbide layer, there arises a problem that the on-resistance of the MOSFET increases. The increase in the on-resistance of the MOSFET reduces the reliability of the MOSFET. For example, by providing a Schottky barrier diode (SBD) operating in a unipolar manner in the MOSFET as a built-in diode, it is possible to suppress the growth of a stacking fault in the silicon carbide layer.

### BRIEF DESCRIPTION OF THE DRAWINGS

FIGS. 1A and 1B are schematic top views of a semiconductor device according to a first embodiment;

FIGS. 2A and 2B are schematic top views of the semiconductor device according to the first embodiment;

FIG. 3 is a schematic cross-sectional view of the semiconductor device according to the first embodiment;

FIG. 4 is an equivalent circuit diagram of the semiconductor device according to the first embodiment;

FIG. 5 is a schematic cross-sectional view of a semiconductor device according to a comparative example;

FIG. 6 is an explanatory diagram of a problem of the semiconductor device according to the comparative example.

FIG. 7 is an explanatory diagram of the function and effect of the semiconductor device according to the first embodiment;

FIG. 8 is an explanatory diagram of the function and effect of the semiconductor device according to the first embodiment; and

FIG. 9 is a schematic cross-sectional view of a semiconductor device according to a second embodiment.

FIG. 10 is a schematic cross-sectional view of a semiconductor device according to a modification example of the second embodiment.

FIG. 11 is a schematic cross-sectional view of a semiconductor device according to a third embodiment.

FIG. 12 is a schematic cross-sectional view of a semiconductor device according to a fourth embodiment.

FIG. 13 is a schematic cross-sectional view of a semiconductor device according to a fifth embodiment.

### DETAILED DESCRIPTION

A semiconductor device of embodiments includes: an element region; and a termination region surrounding the element region. The element region includes: a first electrode; a second electrode; a gate electrode; a silicon carbide layer provided between the first electrode and the second electrode, having a first face on the first electrode side and a second face on the second electrode side, and including a first silicon carbide region of a first conductive type having a first portion in contact with the first face and facing the gate electrode and a second portion in contact with the first face and in contact with the first electrode, a second silicon carbide region of a second conductive type provided between the first silicon carbide region and the first face, a third silicon carbide region of the second conductive type provided between the first silicon carbide region and the first face, provided on the termination region side of the second silicon carbide region, and electrically connected to the first electrode, a fourth silicon carbide region of the second conductive type provided between the first silicon carbide region and the first face, provided between the second silicon carbide region and the third silicon carbide region, facing the gate electrode, and electrically connected to the first electrode, a fifth silicon carbide region of the second conductive type provided between the first silicon carbide region and the first face, provided between the second silicon carbide region and the fourth silicon carbide region, facing the gate electrode, and electrically connected to the first electrode, a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region, a seventh silicon carbide region of the first conductive type provided between the fifth silicon carbide region and the first face and electrically connected to the first electrode, and an eighth silicon carbide region of the second conductive type provided between the sixth silicon carbide region and the first face and having a higher second conductive type impurity concentration than the sixth silicon carbide region; a first silicide layer provided between the eighth silicon carbide region and the first electrode; and a gate insulating layer provided between the gate electrode and the fifth silicon carbide region and between the gate electrode and the first portion. The termination region includes: a wiring layer electrically connected to the first electrode; the second electrode; the silicon carbide layer including the first silicon carbide region having a third portion in contact with the first face and in contact with the wiring layer, a ninth silicon carbide region of the second conductive type provided between the first silicon carbide region and the first face, surrounding the element region, and in contact with the third silicon carbide region, a tenth silicon carbide region of the second conductive type provided between the first silicon carbide region and the first face, surrounding the ninth silicon carbide region, spaced apart from the ninth silicon carbide region, and electrically connected to the wiring layer, and an eleventh silicon carbide region of the second conductive type provided between the tenth silicon carbide region and the first face and having a higher second conductive type impurity concentration than the ninth silicon carbide region and the tenth silicon carbide region; and a second silicide layer provided between the eleventh silicon carbide region and the wiring layer. The first electrode includes a first contact portion in contact with the second portion and a second contact portion in contact with the first silicide layer. The wiring layer includes a third contact portion in contact with the third portion and a fourth contact portion in contact with the second silicide layer. The termination region further includes a third silicide layer provided between the ninth silicon carbide region and the first face and in contact with the ninth silicon carbide region. The wiring layer further includes a fifth contact portion in contact with the third silicide layer.

Hereinafter, embodiments will be described with reference to the diagrams. In the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

In addition, unless otherwise specified in this specification, the “impurity concentration” means a concentration when the impurity concentration of the opposite conductive type is compensated for. That is, the n-type impurity concentration in an n-type silicon carbide region means a concentration obtained by subtracting the concentration of p-type impurities from the concentration of n-type impurities. In addition, the p-type impurity concentration in a p-type silicon carbide region means a concentration obtained by subtracting the concentration of n-type impurities from the concentration of p-type impurities. In addition, unless otherwise specified in this specification, the “impurity concentration in the silicon carbide region” is a maximum impurity concentration in the corresponding silicon carbide region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, distances such as the depth and thickness of the impurity region can be calculated by using, for example, an SIMS or a Scanning Electron Microscope (SEM). In addition, the depth, thickness, and width of an impurity region and a distance such as a gap between impurity regions can be calculated from, for example, a composite image of an SCM image and an atomic force microscope (AFM) image.

### First Embodiment

A semiconductor device according to a first embodiment includes an element region and a termination region surrounding the element region. The element region includes: a first electrode; a second electrode; a gate electrode; a silicon carbide layer provided between the first electrode and the second electrode, having a first face on the first electrode side and a second face on the second electrode side, and including a first silicon carbide region of a first conductive type having a first portion in contact with the first face and facing the gate electrode and a second portion in contact with the first face and in contact with the first electrode, a second silicon carbide region of a second conductive type provided between the first silicon carbide region and the first face, a third silicon carbide region of the second conductive type provided between the first silicon carbide region and the first face, provided on the termination region side of the second silicon carbide region, and electrically connected to the first electrode, a fourth silicon carbide region of the second conductive type provided between the first silicon carbide region and the first face, provided between the second silicon carbide region and the third silicon carbide region, facing the gate electrode, and electrically connected to the first electrode, a fifth silicon carbide region of the second conductive type provided between the first silicon carbide region and the first face, provided between the second silicon carbide region and the fourth silicon carbide region, facing the gate electrode, and electrically connected to the first electrode, a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region, a seventh silicon carbide region of the first conductive type provided between the fifth silicon carbide region and the first face and electrically connected to the first electrode, and an eighth silicon carbide region of the second conductive type provided between the sixth silicon carbide region and the first face and having a higher second conductive type impurity concentration than the sixth silicon carbide region; a first silicide layer provided between the eighth silicon carbide region and the first electrode; and a gate insulating layer provided between the gate electrode and the fifth silicon carbide region and between the gate electrode and the first portion. The termination region includes: a wiring layer electrically connected to the first electrode; the second electrode; the silicon carbide layer including the first silicon carbide region having a third portion in contact with the first face and in contact with the wiring layer, a ninth silicon carbide region of the second conductive type provided between the first silicon carbide region and the first face, surrounding the element region, and in contact with the third silicon carbide region, a tenth silicon carbide region of the second conductive type provided between the first silicon carbide region and the first face, surrounding the ninth silicon carbide region, spaced apart from the ninth silicon carbide region, and electrically connected to the wiring layer, and an eleventh silicon carbide region of the second conductive type provided between the tenth silicon carbide region and the first face and having a higher second conductive type impurity concentration than the ninth silicon carbide region and the tenth silicon carbide region; and a second silicide layer provided between the eleventh silicon carbide region and the wiring layer. The first electrode includes a first contact portion in contact with the second portion and a second contact portion in contact with the first silicide layer. The wiring layer includes a third contact portion in contact with the third portion and a fourth contact portion in contact with the second silicide layer. The termination region further includes a third silicide layer provided between the ninth silicon carbide region and the first face and in contact with the ninth silicon carbide region. The wiring layer further includes a fifth contact portion in contact with the third silicide layer.

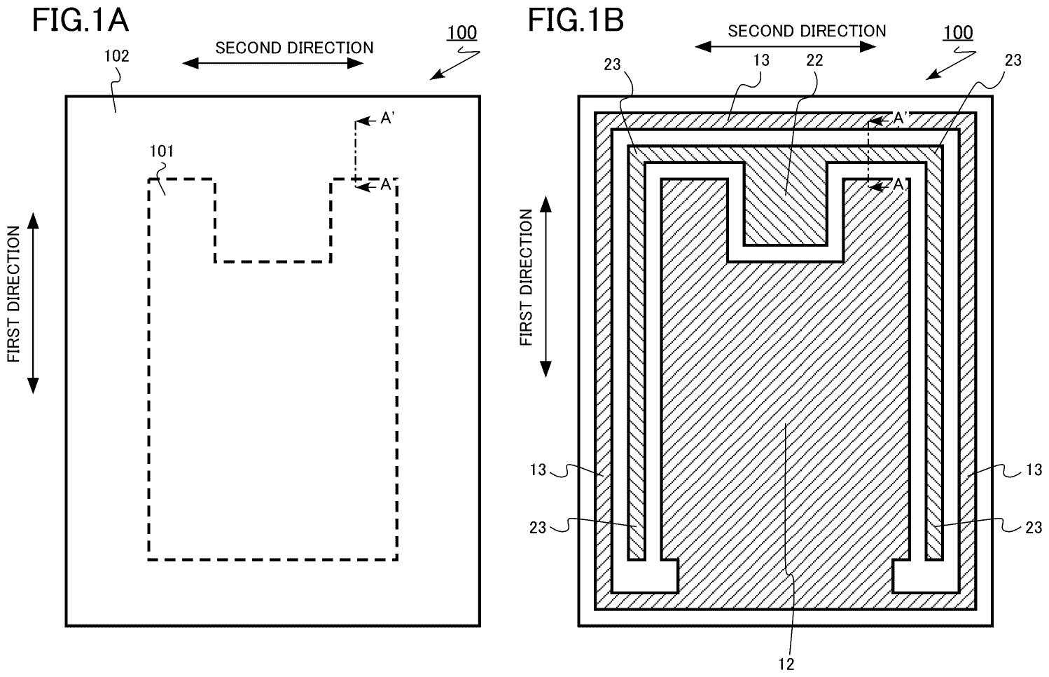

FIGS. 1A and 1B are schematic top views of the semiconductor device according to the first embodiment. FIG. 1A shows a layout pattern of an element region and a termination region. FIG. 1B shows a layout pattern of a source electrode, a source electrode wiring layer, a gate pad electrode, and a gate electrode wiring layer.

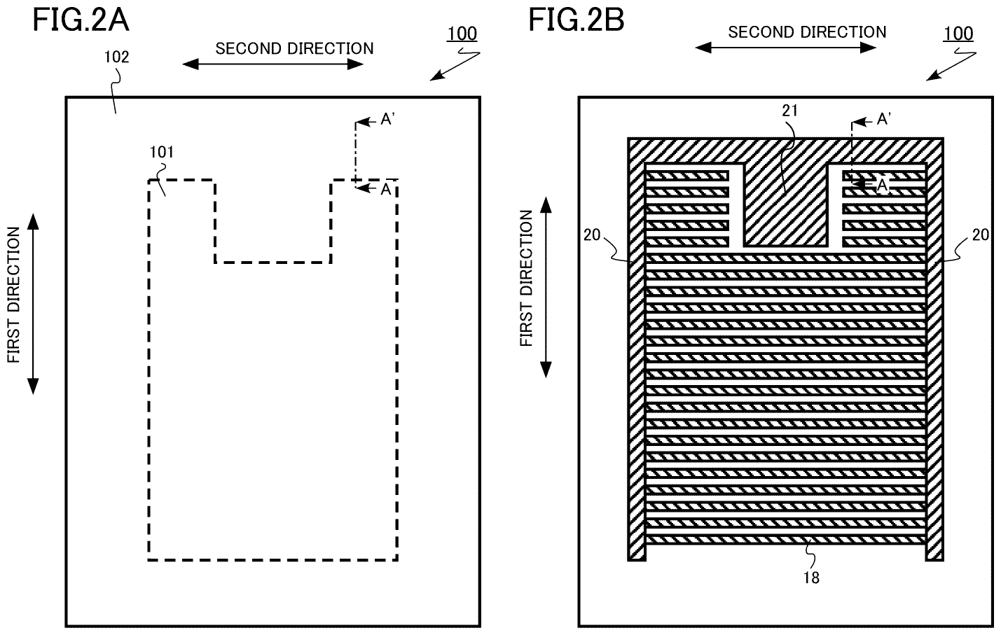

FIGS. 2A and 2B are schematic top views of the semiconductor device according to the first embodiment. FIG. 2A shows a layout pattern of an element region and a termination region. FIG. 2B shows a layout pattern of a gate electrode, a gate connection layer, and a gate pad layer.

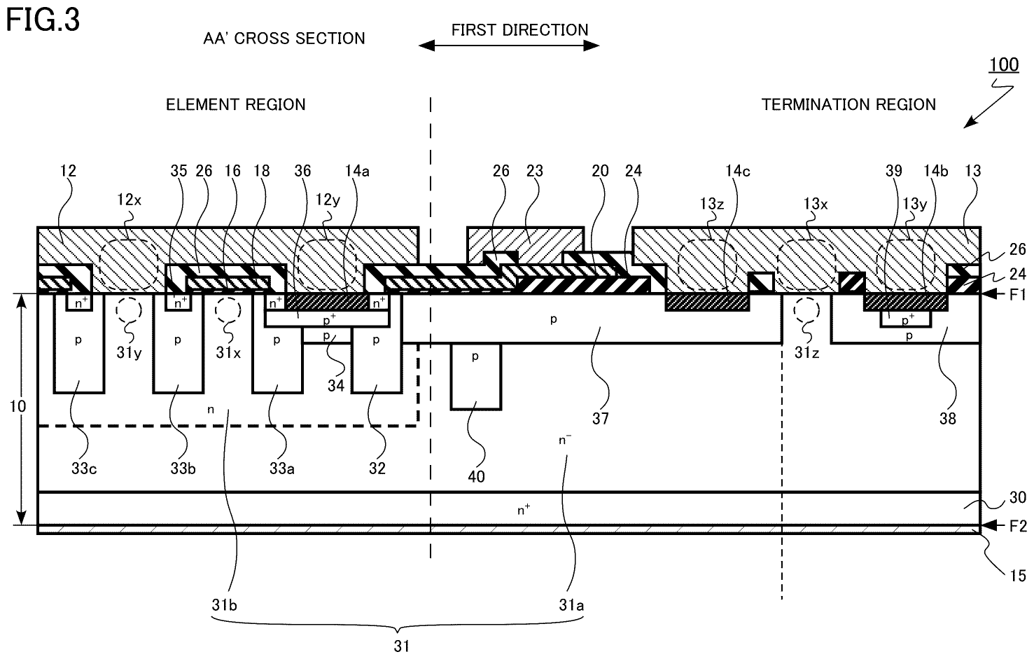

FIG. 3 is a schematic cross-sectional view of the semiconductor device according to the first embodiment. FIG. 3 is a cross-sectional view taken along the line AA′ shown in FIGS. 1A to 2B.

The semiconductor device according to the first embodiment is a planar gate type vertical MOSFET 100 using silicon carbide. The MOSFET 100 is, for example, a double implantation MOSFET (DIMOSFET) in which a base region and a source region are formed by ion implantation. In addition, the semiconductor device according to the first embodiment includes an SBD as a built-in diode.

Hereinafter, a case where the first conductive type is n-type and the second conductive type is p-type will be described as an example. The MOSFET 100 is a vertical n-channel MOSFET having electrons as carriers.

The MOSFET 100 includes a silicon carbide layer 10, a source electrode 12 (first electrode), a source electrode wiring layer 13 (wiring layer), a first silicide layer 14a, a second silicide layer 14b, a third silicide layer 14c, a drain electrode 15 (second electrode), a gate insulating layer 16, a gate electrode 18, a gate connection layer 20, a gate pad layer 21, a gate electrode pad 22, a gate electrode wiring layer 23, a field insulating layer 24, and an interlayer insulating layer 26.

The source electrode 12 includes a first contact portion 12x and a second contact portion 12y. The source electrode wiring layer 13 includes a third contact portion 13x, a fourth contact portion 13y, and a fifth contact portion 13z.

Hereinafter, the first silicide layer 14a, the second silicide layer 14b, and the third silicide layer 14c may be referred to individually or collectively as simply a silicide layer 14.

The silicon carbide layer 10 includes an n⁺-type drain region 30, an n-type drift region 31 (first silicon carbide region), a p-type outer peripheral p region 32 (third silicon carbide region), a first base region 33a of p-type (fourth silicon carbide region), a second base region 33b of p-type (fifth silicon carbide region), a third base region 33c of p-type (second silicon carbide region), a first p region 34 of p-type (sixth silicon carbide region), an n⁺-type source region 35 (seventh silicon carbide region), a first high concentration p region 36 of p⁺-type (eighth silicon carbide region), a second p region 37 of p-type (ninth silicon carbide region), a third p region 38 of p-type (tenth silicon carbide region), a second high concentration p region 39 of p⁺-type (eleventh silicon carbide region), and a fourth p region 40 of p-type (twelfth silicon carbide region). The n-type drift region 31 (first silicon carbide region) has an n⁻-type low concentration region 31a (low concentration region) and an n-type high concentration region 31b (high concentration region). The n-type drift region 31 has a first portion 31x, a second portion 31y, and a third portion 31z.

Hereinafter, the first base region 33a (fourth silicon carbide region), the second base region 33b (fifth silicon carbide region), and the third base region 33c (second silicon carbide region) may be individually or collectively referred to as simply a base region 33.

The MOSFET 100 includes an element region 101 and a termination region 102. The termination region 102 surrounds the element region 101.

The element region 101 includes a plurality of MOSFETs and a plurality of SBDs. The termination region 102 includes an SBD.

The termination region 102 reduces the strength of the electric field applied to the termination portion of the pn junction of the element region 101 when the MOSFET 100 is in an off state. The termination region 102 has a function of increasing the dielectric breakdown voltage of the MOSFET 100.

The element region 101 includes the silicon carbide layer 10, the source electrode 12, the first silicide layer 14a, the drain electrode 15, the gate insulating layer 16, the gate electrode 18, the field insulating layer 24, and the interlayer insulating layer 26. The source electrode 12 in the element region 101 includes the first contact portion 12x and the second contact portion 12y.

The silicon carbide layer 10 in the element region 101 includes the n⁺-type drain region 30, the n-type drift region 31 (first silicon carbide region), the p-type outer peripheral p region 32 (third silicon carbide region), the first base region 33a of p-type (fourth silicon carbide region), the second base region 33b of p-type (fifth silicon carbide region), the third base region 33c of p-type (second silicon carbide region), the first p region 34 of p-type (sixth silicon carbide region), the n⁺-type source region 35 (seventh silicon carbide region), and the first high concentration p region 36 of p⁺-type (eighth silicon carbide region). The drift region 31 of the element region 101 has the n⁻-type low concentration region 31a and the n-type high concentration region 31b. The drift region 31 of the element region 101 has the first portion 31x and the second portion 31y.

The termination region 102 includes the silicon carbide layer 10, the source electrode wiring layer 13, the second silicide layer 14b, the third silicide layer 14c, the drain electrode 15, the gate connection layer 20, the gate pad layer 21, the gate electrode pad 22, the gate electrode wiring layer 23, a field insulating layer 24, and an interlayer insulating layer 26. The source electrode wiring layer 13 in the termination region 102 includes the third contact portion 13x, the fourth contact portion 13y, and the fifth contact portion 13z.

The silicon carbide layer 10 in the termination region 102 includes the n⁺-type drain region 30, the n-type drift region 31 (first silicon carbide region), the second p region 37 of p-type (ninth silicon carbide region), the third p region 38 of p-type (tenth silicon carbide region), the second high concentration p region 39 of p⁺-type (eleventh silicon carbide region), and the fourth p region 40 of p-type (twelfth silicon carbide region). The drift region 31 of the termination region 102 has the third portion 31z.

The silicon carbide layer 10 is provided between the source electrode 12 and the drain electrode 15. The silicon carbide layer 10 is a single crystal SiC. The silicon carbide layer 10 is, for example, 4H-SiC.

The silicon carbide layer 10 has a first face (“F1” in FIG. 3) and a second face (“F2” in FIG. 3). The first face F1 is the surface of the silicon carbide layer. In addition, the second face F2 is the back surface of the silicon carbide layer. Hereinafter, the first face F1 may be referred to as a surface, and the second face F2 may be referred to as a back surface. The first face F1 is disposed on the source electrode 12 side of the silicon carbide layer 10. In addition, the second face F2 is disposed on the drain electrode 15 side of the silicon carbide layer 10. The first face F1 and the second face F2 face each other. Hereinafter, the “depth” means a depth in a direction toward the second face with the first face as a reference. In addition, “face” of the first face F1 and the second face F2 indicates, for example, an interface between a silicon carbide layer and an insulating film or between a silicon carbide layer and a metal.

The first face is parallel to the first and second directions. The second direction is perpendicular to the first direction.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The thickness of the silicon carbide layer 10 is, for example, equal to or more than 5 μm and equal to or less than 350 μm.

The n⁺-type drain region 30 is provided on the back surface side of the silicon carbide layer 10. The drain region 30 contains, for example, nitrogen (N) as an n-type impurity. The n-type impurity concentration in the drain region 30 is equal to or more than 1×10¹⁸ cm⁻³ and equal to or less than 1×10²¹ cm⁻³, for example.

The n-type drift region 31 is provided between the drain region 30 and the first face F1. The n-type drift region 31 is provided between the source electrode 12 and the drain electrode 15. The n-type drift region 31 is provided between the gate electrode 18 and the drain electrode 15. The n-type drift region 31 is provided on the drain region 30.

The drift region 31 contains, for example, nitrogen (N) as an n-type impurity. The n-type impurity concentration in the drift region 31 is lower than the n-type impurity concentration in the drain region 30. The n-type impurity concentration in the drift region 31 is equal to or more than 4×10¹⁴ cm⁻³ and equal to or less than 5×10¹⁷ cm⁻³, for example. The thickness of the drift region 31 is, for example, equal to or more than 3 μm and equal to or less than 100 μm.

The drift region 31 has the n⁻-type low concentration region 31a and the n-type high concentration region 31b in the element region 101. The high concentration region 31b is provided between the low concentration region 31a and the first face F1.

By having the n⁻-type low concentration region 31a, for example, the dielectric breakdown voltage of the MOSFET 100 increases. In addition, by having the n-type high concentration region 31b, for example, the on-current of the MOSFET 100 increases.

The drift region 31 includes the first portion 31x and the second portion 31y in the element region 101. The first portion 31x and the second portion 31y are included in the high concentration region 31b.

The first portion 31x is in contact with the first face F1, and faces the gate electrode 18 with the gate insulating layer 16 interposed therebetween. The first portion 31x functions as, for example, a current path for the MOSFET in the element region 101.

The second portion 31y is in contact with the first face F1, and is in contact with the source electrode 12. The second portion 31y functions as, for example, a current path for the SBD in the element region 101. In the second direction of the second portion 31y, for example, a silicide layer (not shown) is provided.

The p-type base region 33 is provided between the drift region 31 and the first face F1. The base region 33 is provided between the high concentration region 31b and the first face F1.

The base region 33 extends, for example, in the second direction. For example, a plurality of base regions 33 are repeatedly arranged in the first direction.

The base region 33 includes, for example, the first base region 33a, the second base region 33b, and the third base region 33c of p-type. The first base region 33a is provided between the third base region 33c and the outer peripheral p region 32. The second base region 33b is provided between the third base region 33c and the first base region 33a.

The base region 33 functions as, for example, a channel region of the MOSFET 100.

The width of the base region 33 is, for example, equal to or more than 0.5 μm and equal to or less than 2.0 μm. The width of the first base region 33a in the first direction is, for example, equal to or more than 0.5 μm and equal to or less than 2.0 μm.

The distance in the first direction between the two base regions 33 adjacent to each other in the first direction is, for example, equal to or more than 0.5 μm and equal to or less than 2.0 μm. The distance in the first direction between the first base region 33a and the second base region 33b is, for example, equal to or more than 0.5 μm and equal to or less than 2.0 μm.

The depth of the base region 33 is, for example, equal to or more than 1.0 μm and equal to or less than 2.0 μm. By deepening the base region 33, for example, the amount of current when a short-circuit current flows through the MOSFET 100 is suppressed, thereby improving the short-circuit resistance of the MOSFET 100.

The base region 33 is electrically connected to the source electrode 12. The base region 33 is fixed to the electric potential of the source electrode 12.

A part of the base region 33 is in contact with the first face F1. A part of the base region 33 faces the gate electrode 18. For example, a part of the first base region 33a faces the gate electrode 18. For example, a part of the second base region 33b faces the gate electrode 18. The gate insulating layer 16 is interposed between a part of the base region 33 and the gate electrode 18.

The base region 33 contains, for example, aluminum (Al) as a p-type impurity. The p-type impurity concentration in the base region 33 is, for example, equal to or more than 5×10¹⁷ cm⁻³ and equal to or less than 1×10²⁰ cm⁻³.

The p-type outer peripheral p region 32 is provided between the drift region 31 and the first face F1. The outer peripheral p region 32 is provided between the high concentration region 31b and the first face F1.

The outer peripheral p region 32 is provided on the outer periphery of the base region 33. The outer peripheral p region 32 is provided on the termination region 102 side of the base region 33. The outer peripheral p region 32 is provided on the termination region 102 side of the third base region 33c. For example, the outer peripheral p region 32 surrounds the base region 33 on the first face F1.

The width of the outer peripheral p region 32 in the first direction is, for example, equal to or more than 0.5 μm and equal to or less than 2.0 μm. The width of the outer peripheral p region 32 in the first direction is substantially the same as the width of the base region 33 in the first direction, for example.

The distance in the first direction between the outer peripheral p region 32 and the first base region 33a is, for example, equal to or more than 0.5 μm and equal to or less than 2.0 μm. For example, the distance in the first direction between the outer peripheral p region 32 and the first base region 33a is substantially equal to the distance in the first direction between the two base regions 33 adjacent to each other in the first direction.

A depth of the outer peripheral p region 32 is, for example, equal to or more than 1.0 μm and equal to or less than 2.0 μm. The depth of the outer peripheral p region 32 is substantially the same as the depth of the base region 33, for example.

The outer peripheral p region 32 is electrically connected to the source electrode 12. The outer peripheral p region 32 is fixed at the electric potential of the source electrode 12.

The outer peripheral p region 32 contains, for example, aluminum (Al) as a p-type impurity. The p-type impurity concentration in the outer peripheral p region 32 is, for example, equal to or more than 5×10¹⁷ cm⁻³ and equal to or less than 1×10²⁰ cm⁻³. The p-type impurity concentration in the outer peripheral p region 32 is substantially the same as the p-type impurity concentration in the base region 33, for example.

The outer peripheral p region 32 is formed by the same manufacturing process using the same mask pattern as for the base region 33, for example.

The first p region 34 of p-type is provided between the drift region 31 and the first face F1. The first p region 34 is provided between the high concentration region 31b and the first face F1.

The first p region 34 is provided, for example, between the two base regions 33 adjacent to each other in the first direction. The first p region 34 is provided between the outer peripheral p region 32 and the first base region 33a. The first p region 34 is in contact with the outer peripheral p region 32 and the first base region 33a.

The first p region 34 is provided between the first high concentration p region 36 and the high concentration region 31b. The first p region 34 is provided between the silicide layer 14 and the high concentration region 31b.

The depth of the first p region 34 is smaller than the depth of the outer peripheral p region 32 and the depth of the base region 33. The depth of the first p region 34 is smaller than the depth of the first base region 33a, for example. The depth of the first p region 34 is, for example, equal to or more than 0.5 μm and equal to or less than 1μ m.

By providing the first p region 34 with a depth smaller than the depth of the base region 33, when a forward current flows through the SBD in the element region 101, the current is promoted to flow around the bottom portion of the base region 33. Therefore, the operation start voltage of the pn junction diode having the base region 33 as its anode can be increased.

The first p region 34 is electrically connected to the source electrode 12. The first p region 34 is fixed to the electric potential of the source electrode 12.

The first p region 34 contains, for example, aluminum (Al) as a p-type impurity. The p-type impurity concentration in the first p region 34 is, for example, equal to or more than 5×10¹⁷ cm⁻³ and equal to or less than 1×10²⁰ cm⁻³.

The drift region 31 includes the third portion 31z in the termination region 102. The third portion 31z is in contact with the first face F1 and is in contact with the source electrode wiring layer 13. The third portion 31z functions as, for example, a current path for the SBD in the termination region 102.

The second p region 37 of p-type is provided between the drift region 31 and the first face F1. The second p region 37 is provided between the low concentration region 31a and the first face F1.

The second p region 37 surrounds the element region 101. The second p region 37 is in contact with the outer peripheral p region 32.

The depth of the second p region 37 is smaller than the depth of the outer peripheral p region 32 and the depth of the base region 33. The depth of the second p region 37 is smaller than the depth of the first base region 33a, for example. The depth of the second p region 37 is, for example, equal to or more than 0.5 μm and equal to or less than 1μ m.

The depth of the second p region 37 is substantially the same as the depth of the first p region 34, for example.

The second p region 37 is electrically connected to the source electrode wiring layer 13. The second p region 37 is fixed to the electric potential of the source electrode wiring layer 13. The second p region 37 is fixed to the electric potential of the source electrode 12.

The second p region 37 contains, for example, aluminum (Al) as a p-type impurity. The p-type impurity concentration in the second p region 37 is, for example, equal to or more than 5×10¹⁷ cm⁻³ and equal to or less than 1×10²⁰ cm⁻³. The p-type impurity concentration in the second p region 37 is substantially the same as the p-type impurity concentration in the first p region 34, for example.

The second p region 37 is formed by the same manufacturing process using the same mask pattern as for the first p region 34, for example.

The third p region 38 of p-type is provided between the drift region 31 and the first face F1. The third p region 38 is provided between the low concentration region 31a and the first face F1.

The third p region 38 surrounds the second p region 37. The third p region 38 is spaced apart from the second p region 37 in the first direction.

The drift region 31 is provided between the third p region 38 and the second p region 37. The third portion 31z of the drift region 31 is provided between the third p region 38 and the second p region 37.

The depth of the third p region 38 is smaller than the depth of the outer peripheral p region 32 and the depth of the base region 33. The depth of the third p region 38 is, for example, smaller than the depth of the first base region 33a. The depth of the third p region 38 is, for example, equal to or more than 0.5 μm and equal to or less than 1 μm.

The depth of the third p region 38 is substantially the same as the depth of the first p region 34 and the depth of the second p region 37, for example.

The third p region 38 is electrically connected to the source electrode 12. The third p region 38 is fixed to the electric potential of the source electrode 12.

The third p region 38 contains, for example, aluminum (Al) as a p-type impurity. The p-type impurity concentration in the third p region 38 is, for example, equal to or more than 5×10¹⁷ cm⁻³ and equal to or less than 1×10²⁰ cm⁻³. The p-type impurity concentration in the third p region 38 is substantially the same as the p-type impurity concentration in the first p region 34 and the p-type impurity concentration in the second p region 37, for example.

The third p region 38 is formed by the same manufacturing process using the same mask pattern as for the first p region 34 and the second p region 37, for example.

The fourth p region 40 of p-type is provided between the drift region 31 and the first face F1. The fourth p region 40 is provided between the drift region 31 and the second p region 37.

The fourth p region 40 is provided, for example, between the low concentration region 31a and the first face F1. The fourth p region 40 is provided, for example, between the low concentration region 31a and the second p region 37. The fourth p region 40 is in contact with, for example, the low concentration region 31a.

The fourth p region 40 is provided on the outer periphery of the outer peripheral p region 32. The fourth p region 40 is provided on the termination region 102 side of the outer peripheral p region 32. The fourth p region 40 is spaced apart from the outer peripheral p region 32 in the first direction. For example, the fourth p region 40 surrounds the outer peripheral p region 32 on the first face F1.

A width of the fourth p region 40 in the first direction is, for example, equal to or more than 0.5 times and equal to or less than 3 times the width of the base region 33 in the first direction. The width of the fourth p region 40 in the first direction is equal to or more than 0.5 times and equal to or less than 3 times a width of the first base region 33a in the first direction. The width of the fourth p region 40 in the first direction is, for example, equal to or more than 0.5 μm and equal to or less than 10 μm. The width of the fourth p region 40 in the first direction is substantially the same as the width of the base region 33 in the first direction, for example.

A distance in the first direction between the fourth p region 40 and the outer peripheral p region 32 is equal to or more than 0.5 times and equal to or less than 3 times a distance in the first direction between the first base region 33a and the second base region 33b. The distance in the first direction between the fourth p region 40 and the outer peripheral p region 32 is, for example, equal to or more than 0.5 μm and equal to or less than 2.0 μm.

The fourth p region 40 is provided closer to the element region 101 than the end portion of the field insulating layer 24 in the termination region 102 on the element region 101 side, for example.

A depth of the fourth p region 40 is larger than the depth of the second p region 37. The depth of the fourth p region 40 is, for example, equal to or more than 1.0 μm and equal to or less than 2.0 μm. The depth of the fourth p region 40 is, for example, equal to or more than 1.5 times and equal to or less than 5 times the depth of the second p region 37.

The depth of the fourth p region 40 is, for example, equal to or more than 0.5 times and equal to or less than 2 times the depth of the base region 33. The depth of the fourth p region 40 is, for example, equal to or more than the depth of the base region 33. The first depth of the fourth p region 40 is, for example, larger than the depth of the base region 33.

The depth of the fourth p region 40 is, for example, equal to or more than 0.5 times and equal to or less than 2 times the depth of the outer peripheral p region 32. The depth d1 of the fourth p region 40 is, for example, equal to or more than the depth of the outer peripheral p region 32. The depth of the fourth p region 40 is, for example, larger than the depth d2 of the outer peripheral p region 32.

The fourth p region 40 is electrically connected to the source electrode 12. The fourth p region 40 is fixed to the electric potential of the source electrode 12.

The fourth p region 40 contains, for example, aluminum (Al) as a p-type impurity. The p-type impurity concentration in the fourth p region 40 is, for example, equal to or more than 1×10¹⁷ cm⁻³ and equal to or less than 1×10²⁰ cm⁻³.

The p-type impurity concentration in the fourth p region 40 is, for example, equal to or more than 0.1 times and equal to or less than 2 times the p-type impurity concentration in the base region 33. The p-type impurity concentration in the fourth p region 40 is substantially the same as the p-type impurity concentration in the base region 33, for example.

The p-type impurity concentration in the fourth p region 40 is, for example, equal to or more than 0.1 times and equal to or less than 2 times the p-type impurity concentration in the outer peripheral p region 32. The p-type impurity concentration in the fourth p region 40 is substantially the same as the p-type impurity concentration in the outer peripheral p region 32, for example.

The fourth p region 40 is formed by the same manufacturing process using the same mask pattern as for the base region 33 and the outer peripheral p region 32, for example.

By providing the fourth p region 40, the strength of the electric field applied to the termination portion of the pn junction in the element region 101 is further reduced. Therefore, the provision of the fourth p region 40 further increases the dielectric breakdown voltage of the MOSFET 100.

The n⁺-type source region 35 is provided between the base region 33 and the first face F1. The source region 35 is provided, for example, between the second base region 33b and the first face F1. The source region 35 extends, for example, in the first direction.

The source region 35 contains, for example, phosphorus (P) or nitrogen (N) as an n-type impurity. The n-type impurity concentration in the source region 35 is higher than the n-type impurity concentration in the drift region 31.

The n-type impurity concentration in the source region 35 is, for example, equal to or more than 1×10¹⁹ cm⁻³ and equal to or less than 1×10²¹ cm⁻³. The depth of the source region 35 is smaller than the depth of the first p region 34. The depth of the source region 35 is, for example, equal to or more than 0.05 μm and equal to or less than 0.2 μm.

The source region 35 is electrically connected to the source electrode 12. The source region 35 is in contact with the silicide layer 14. The contact between the source region 35 and the source electrode 12 is, for example, an ohmic contact. The source region 35 is fixed to the electric potential of the source electrode 12.

The first high concentration p region 36 of p⁺-type is provided between the first p region 34 and the first face F1. The first high concentration p region 36 is provided between the first p region 34 and the first silicide layer 14a.

The first high concentration p region 36 contains, for example, aluminum (Al) as a p-type impurity. The p-type impurity concentration in the first high concentration p region 36 is higher than the p-type impurity concentration in the first p region 34. The p-type impurity concentration in the first high concentration p region 36 is, for example, equal to or more than 10 times and equal to or less than 1000 times the p-type impurity concentration in the first p region 34.

The p-type impurity concentration in the first high concentration p region 36 is, for example, equal to or more than 1×10¹⁹ cm⁻³ and equal to or less than 1×10²¹ cm⁻³. The depth of the first high concentration p region 36 is, for example, equal to or more than 0.1 μm and equal to or less than 0.2 μm.

The first high concentration p region 36 is electrically connected to the source electrode 12. The first high concentration p region 36 is in contact with the first silicide layer 14a.

The second high concentration p region 39 of p⁺-type is provided between the third p region 38 and the first face F1. The second high concentration p region 39 is provided between the third p region 38 and the second silicide layer 14b.

The second high concentration p region 39 contains, for example, aluminum (Al) as a p-type impurity. The p-type impurity concentration in the second high concentration p region 39 is higher than the p-type impurity concentration in the second p region 37 and the p-type impurity concentration in the third p region 38. The p-type impurity concentration in the second high concentration p region 39 is, for example, equal to or more than 10 times and equal to or less than 1000 times the p-type impurity concentration in the third p region 38.

The p-type impurity concentration in the second high concentration p region 39 is, for example, equal to or more than 1×10¹⁹ cm⁻³ and equal to or less than 1×10²¹ cm⁻³. The depth of the second high concentration p region 39 is, for example, equal to or more than 0.1 μm and equal to or less than 0.2 μm.

The second high concentration p region 39 is electrically connected to the source electrode wiring layer 13. The second high concentration p region 39 is in contact with the second silicide layer 14b.

The second high concentration p region 39 is formed by the same manufacturing process using the same mask pattern as for the first high concentration p region 36, for example.

The first silicide layer 14a is provided between the first high concentration p region 36 and the source electrode 12. The first silicide layer 14a is in contact with the first high concentration p region 36 and the source region 35.

The second silicide layer 14b is provided between the second high concentration p region 39 and the source electrode wiring layer 13. The second silicide layer 14b is in contact with the second high concentration p region 39.

The third silicide layer 14c is provided between the second p region 37 and the source electrode wiring layer 13. The third silicide layer 14c is in contact with the second p region 37.

The silicide layer 14 contains silicide. The silicide layer 14 contains, for example, nickel (Ni) or titanium (Ti). The silicide layer 14 is, for example, a nickel silicide or a titanium silicide.

The gate electrode 18 is provided on the first face F1 side of the silicon carbide layer 10. The gate electrode 18 extends, for example, in the second direction. A plurality of gate electrodes 18 are arranged, for example, in parallel to each other in the first direction. The gate electrode 18 has, for example, a striped shape.

The gate electrode 18 is a conductive layer. The gate electrode 18 is, for example, polycrystalline silicon containing p-type impurities or n-type impurities.

The gate electrode 18 faces the base region 33. The gate electrode 18 faces the first portion 31x.

The gate connection layer 20 is provided on the first face F1 side of the silicon carbide layer 10. The gate connection layer 20 is provided on the gate insulating layer 16 or the field insulating layer 24.

A part of the gate connection layer 20 extends, for example, in a direction perpendicular to the gate electrode 18. The gate connection layer 20 has a function of electrically connecting the gate electrode 18 and the gate electrode pad 22 to each other.

The gate connection layer 20 is formed of, for example, the same material as the gate electrode 18.

The gate pad layer 21 is provided on the first face F1 side of the silicon carbide layer 10. The gate pad layer 21 is provided on the field insulating layer 24. The gate pad layer 21 is physically and

electrically connected to the gate connection layer 20. The gate pad layer 21 has a function of electrically connecting the gate electrode 18 and the gate electrode pad 22 to each other.

The gate pad layer 21 is formed of, for example, the same material as the gate electrode 18 and the gate connection layer 20.

The gate insulating layer 16 is provided between the gate electrode 18 and the base region 33. The gate insulating layer 16 is provided between the gate electrode 18 and the first portion 31x. The gate insulating layer 16 is provided between the gate electrode 18 and the source region 35.

The gate insulating layer 16 is, for example, a silicon oxide. For example, a high-k insulating material (insulating material with a high dielectric constant) can be applied to the gate insulating layer 16.

The field insulating layer 24 is provided on the silicon carbide layer 10 in the termination region 102. The field insulating layer 24 is, for example, a silicon oxide.

The interlayer insulating layer 26 is provided on the gate electrode 18 and the silicon carbide layer 10. The interlayer insulating layer 26 is, for example, a silicon oxide.

The source electrode 12 is provided on the first face F1 side of the silicon carbide layer 10 in the element region 101. The source electrode 12 is provided on the interlayer insulating layer 26.

The source electrode 12 contains metal. The source electrode 12 has a stacked structure of, for example, a first film containing titanium (Ti) and a second film containing aluminum (Al). The source electrode 12 is, for example, a stacked film of a titanium film and an aluminum film. The source electrode 12 does not contain silicide, for example.

The source electrode 12 contains the first contact portion 12x and the second contact portion 12y.

The first contact portion 12x is in contact with the second portion 31y of the drift region 31. No silicide layer is provided between the first contact portion 12x and the second portion 31y. The contact between the first contact portion 12x and the second portion 31y is a Schottky contact.

A part of the first contact portion 12x is in contact with, for example, the base region 33.

The first contact portion 12x functions as an anode electrode of the SBD in the element region 101.

The second contact portion 12y is in contact with the first silicide layer 14a. The first silicide layer 14a is in contact with the first high concentration p region 36 and the source region 35.

The contact resistance between the second contact portion 12y and the first high concentration p region 36 is reduced by interposing the first silicide layer 14a therebetween. The contact between the second contact portion 12y and the first high concentration p region 36 is, for example, an ohmic contact.

The contact resistance between the second contact portion 12y and the source region 35 is reduced by interposing the first silicide layer 14a therebetween. The contact between the second contact portion 12y and the source region 35 is, for example, an ohmic contact.

The second contact portion 12y has a function of fixing the electric potentials of the base region 33, the first p region 34, and the second p region 37 to the electric potential of the source electrode 12, for example.

The source electrode wiring layer 13 is provided on the first face F1 side of the silicon carbide layer 10 in the termination region 102. The source electrode wiring layer 13 is provided on the interlayer insulating layer 26.

The source electrode wiring layer 13 is physically and electrically connected to the source electrode 12. The source electrode wiring layer 13 surrounds the source electrode 12, for example.

The source electrode wiring layer 13 contains metal. The source electrode wiring layer 13 has a stacked structure of a first film containing titanium (Ti) and a second film containing aluminum (Al), for example. The source electrode wiring layer 13 is, for example, a stacked film of a titanium film and an aluminum film. The source electrode wiring layer 13 does not contain, for example, silicide.

The source electrode wiring layer 13 is formed of, for example, the same material as the source electrode 12.

The source electrode wiring layer 13 includes the third contact portion 13x, the fourth contact portion 13y, and the fifth contact portion 13z.

The fourth contact portion 13y is provided, for example, at the end of the third p region 38 on the second p region 37 side. The fifth contact portion 13z is provided, for example, at the end of the second p region 37 on the third p region 38 side.

The third contact portion 13x is provided between the fourth contact portion 13y and the fifth contact portion 13z. Between the third contact portion 13x and the fourth contact portion 13y, for example, the interlayer insulating layer 26 is provided. Between the third contact portion 13x and the fifth contact portion 13z, for example, the interlayer insulating layer 26 is provided.

The distance in the first direction between the third contact portion 13x and the fourth contact portion 13y is, for example, substantially the same as the distance in the first direction between the third contact portion 13x and the fifth contact portion 13z. The distance in the first direction between the third contact portion 13x and the fourth contact portion 13y is, for example, equal to or more than 0.5 times and equal to or less than 2 times the distance in the first direction between the third contact portion 13x and the fifth contact portion 13z.

The third contact portion 13x is in contact with the third portion 31z of the drift region 31. No silicide layer is provided between the third contact portion 13x and the third portion 31z. The contact between the third contact portion 13x and the third portion 31z is a Schottky contact.

A part of the third contact portion 13x is in contact with, for example, the second p region 37. Another part of the third contact portion 13x is in contact with, for example, the third p region 38.

The third contact portion 13x functions as an anode electrode of the SBD in the termination region 102.

The fourth contact portion 13y is in contact with the second silicide layer 14b. The second silicide layer 14b is in contact with the second high concentration p region 39 and the third p region 38.

The contact resistance between the fourth contact portion 13y and the second high concentration p region 39 is reduced by interposing the second silicide layer 14b therebetween. The contact between the fourth contact portion 13y and the second high concentration p region 39 is, for example, an ohmic contact.

The fourth contact portion 13y has a function of fixing the electric potential of the third p region 38 to the electric potential of the source electrode 12 and the source electrode wiring layer 13, for example.

The fifth contact portion 13z is in contact with the third silicide layer 14c. The third silicide layer 14c is in contact with the second p region 37.

The contact resistance between the fifth contact portion 13z and the second p region 37 is reduced by interposing the third silicide layer 14c therebetween.

The fifth contact portion 13z has a function of fixing the electric potential of the second p region 37 to the electric potential of the source electrode 12 and the source electrode wiring layer 13, for example.

The electrical resistance between the fifth contact portion 13z and the second p region 37 of the MOSFET 100 is higher than the electrical resistance between the fourth contact portion 13y and the third p region 38. Since no region with a high p-type impurity concentration is provided between the fifth contact portion 13z and the second p region 37, the electrical resistance increases.

The third silicide layer 14c is in contact with the second p region 37. The p-type impurity concentration in the second p region 37 is lower than the p-type impurity concentration in the second high concentration p region 39. The p-type impurity concentration in a portion of the second p region 37 in contact with the third silicide layer 14c is, for example, equal to or more than 1/1000 and equal to or less than 1/10 of the p-type impurity concentration in a portion of the second high concentration p region 39 in contact with the second silicide layer 14b.

The gate electrode pad 22 is provided on the first face F1 side of the silicon carbide layer 10 in the termination region 102. The gate electrode pad 22 is provided on the interlayer insulating layer 26.

The gate electrode pad 22 contains metal. The gate electrode pad 22 is formed of, for example, the same material as the source electrode 12 and the source electrode wiring layer 13.

The gate electrode wiring layer 23 is provided on the first face F1 side of the silicon carbide layer 10 in the termination region 102. The gate electrode wiring layer 23 is provided on the interlayer insulating layer 26.

The gate electrode wiring layer 23 is physically and electrically connected to the gate electrode pad 22. The gate electrode wiring layer 23 is physically and electrically connected to the gate connection layer 20. The gate electrode wiring layer 23 contains metal. The gate electrode wiring layer 23 is formed of, for example, the same material as the source electrode 12, the source electrode wiring layer 13, and the gate electrode pad 22.

The drain electrode 15 is provided on the back surface of the silicon carbide layer 10. The drain electrode 15 is in contact with the drain region 30.

The drain electrode 15 is, for example, a metal or a metal semiconductor compound. The drain electrode 15 contains at least one material selected from a group consisting of nickel silicide, titanium (Ti), nickel (Ni), silver (Ag), and gold (Au), for example.

In the element region 101, the gate electrode 18, the gate insulating layer 16, the base region 33, the source region 35, the first portion 31x of the drift region 31, the drain region 30, the second contact portion 12y of the source electrode 12, and the drain electrode 15 form a MOSFET. When the MOSFET 100 is in an on state, a current flows from the drain electrode 15 to the source electrode 12 due to the MOSFET in the element region 101.

In the element region 101, the first contact portion 12x of the source electrode 12, the second portion 31y of the drift region 31, the drain region 30, and the drain electrode 15 form an SBD. When a voltage positive with respect to the drain electrode 15 is applied to the source electrode 12 while the MOSFET 100 is in an off state, a current flows from the source electrode 12 to the drain electrode 15 due to the SBD in the element region 101.

In the termination region 102, the third contact portion 13x of the source electrode wiring layer 13, the third portion 31z of the drift region 31, the drain region 30, and the drain electrode 15 form an SBD. When a voltage positive with respect to the drain electrode 15 is applied to the source electrode 12 while the MOSFET 100 is in an off state, a current flows from the source electrode wiring layer 13 to the drain electrode 15 due to the SBD in the termination region 102.

Next, the function and effect of the MOSFET 100 according to the first embodiment will be described.

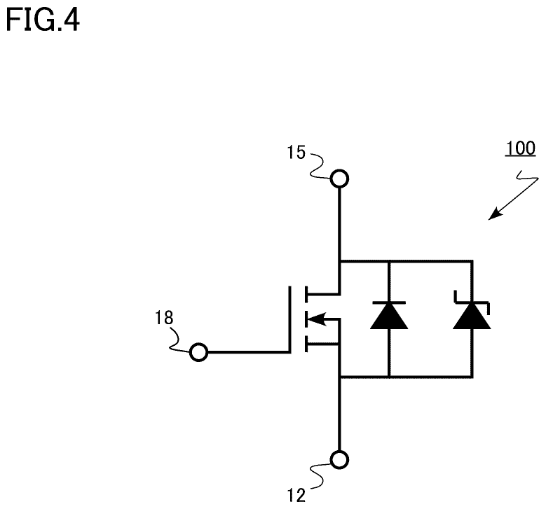

FIG. 4 is an equivalent circuit diagram of the semiconductor device according to the first embodiment. In the MOSFET 100, between the source electrode 12 and the drain electrode 15 in the element region 101, a pn junction diode and an SBD are connected as built-in diodes in parallel with a transistor. The base region 33 is on the anode side of the pn junction diode, and the drift region 31 is on the cathode side of the pn junction diode. In addition, the source electrode 12 serves as the anode of the SBD, and the drain electrode 15 serves as the cathode of the SBD.

For example, a case where the MOSFET 100 is used as a switching element connected to an inductive load is considered. When the MOSFET 100 is turned off, a voltage that is positive with respect to the drain electrode 15 may be applied to the source electrode 12 due to an induced current caused by an inductive load. In this case, a forward current flows through the built-in diode. This state is also referred to as a reverse conduction state.

If the MOSFET does not include an SBD, a forward current flows through the pn junction diode. The pn junction diode operates in a bipolar manner. When a reflux current is made to flow by using a pn junction diode that operates in a bipolar manner, a stacking fault grows in a silicon carbide layer due to the recombination energy of the carriers. When the stacking fault grows in the silicon carbide layer, there arises a problem that the on-resistance of the MOSFET increases. Increasing the on-resistance of the MOSFET leads to a reduction in the reliability of the MOSFET.

The MOSFET 100 includes an SBD. A forward voltage (Vf) at which a forward current starts to flow through the SBD is lower than a forward voltage (Vf) of the pn junction diode. Therefore, a forward current flows through the SBD prior to the pn junction diode.

The forward voltage (Vf) of the SBD is, for example, equal to or more than 1.0 V and less than 2.0 V.

The forward voltage (Vf) of the pn junction diode is, for example, equal to or more than 2.0 V and equal to or less than 3.0 V.

The SBD operates in a unipolar manner. Therefore, even if a forward current flows, no stacking fault grows in the silicon carbide layer 10 due to the recombination energy of the carriers. Therefore, the increase in the on-resistance of the MOSFET 100 is suppressed. As a result, the reliability of the MOSFET 100 is improved.

In addition, since the forward current flows through the SBD, the voltage on the N side of the pn junction diode rises, and the voltage applied to the pn junction in the vicinity of the SBD effectively drops. Therefore, by providing the SBD, the forward voltage (Vf) of the pn junction diode in the vicinity of the SBD can be effectively increased. Therefore, the flow of the forward current to the pn junction diode is suppressed. In other words, the operation start voltage of the pn junction diode can be increased. As a result, the reliability of the MOSFET 100 is improved.

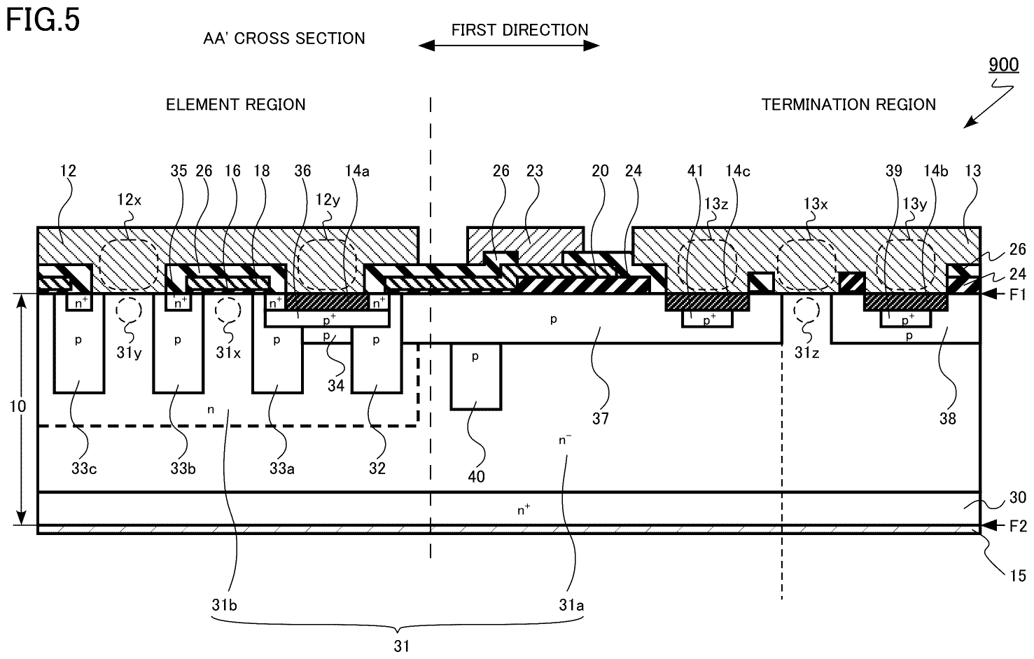

FIG. 5 is a schematic cross-sectional view of a semiconductor device according to a comparative example. The semiconductor device according to the comparative example is a MOSFET 900. FIG. 5 is a diagram corresponding to FIG. 3 in the first embodiment.

The MOSFET 900 according to the comparative example is different from the MOSFET 100 according to the first embodiment in that a third high concentration p region 41 of p⁺-type (thirteenth silicon carbide region) is provided between the third silicide layer 14c and the second p region 37 of p-type.

The third high concentration p region 41 of p⁺-type is provided between the second p region 37 and the first face F1. The third high concentration p region 41 is provided between the second p region 37 and the third silicide layer 14c.

The third high concentration p region 41 contains, for example, aluminum (Al) as a p-type impurity. The p-type impurity concentration in the third high concentration p region 41 is higher than the p-type impurity concentration in the second p region 37 and the p-type impurity concentration in the third p region 38. The p-type impurity concentration in the third high concentration p region 41 is, for example, equal to or more than 10 times and equal to or less than 1000 times the p-type impurity concentration in the second p region 37.

The p-type impurity concentration in the third high concentration p region 41 is, for example, equal to or more than 1×10¹⁹ cm⁻³ and equal to or less than 1×10²¹ cm⁻³. The depth of the third high concentration p region 41 is, for example, equal to or more than 0.1 μm and equal to or less than 0.2 μm.

The third high concentration p region 41 is electrically connected to the source electrode wiring layer 13. The third high concentration p region 41 is in contact with the second silicide layer 14b.

The third high concentration p region 41 is formed by the same manufacturing process using the same mask pattern as for the first high concentration p region 36 and the second high concentration p region 39, for example.

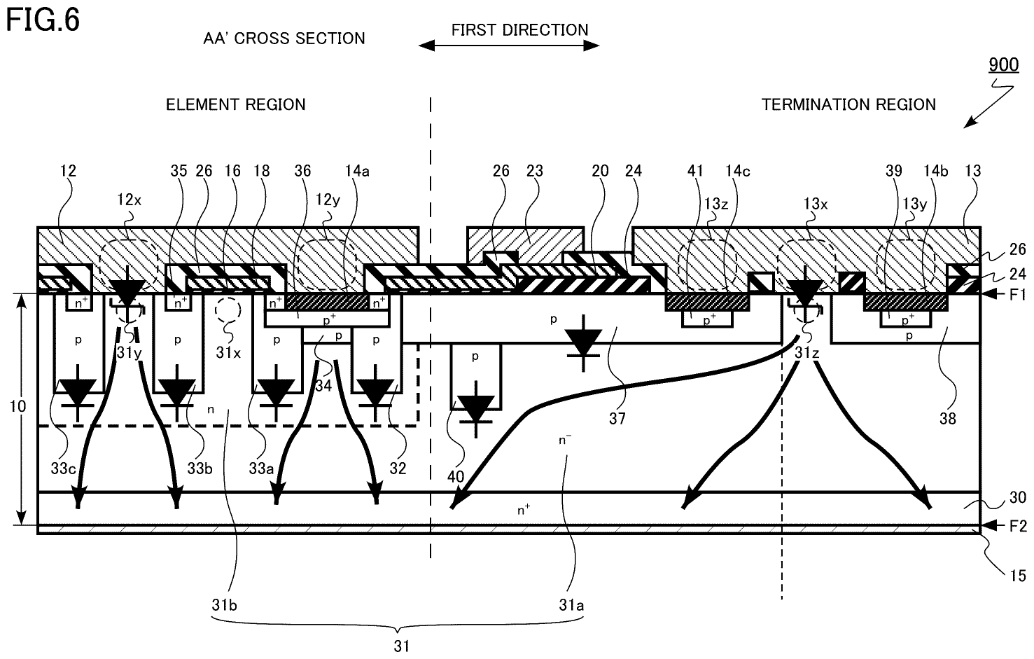

FIG. 6 is an explanatory diagram of the function and effect of the semiconductor device according to the comparative example. FIG. 6 is a schematic cross-sectional view of the semiconductor device according to the comparative example. FIG. 6 is a diagram corresponding to FIG. 5.

FIG. 6 shows pn junction diodes and SBDs built in the MOSFET 900 using circuit symbols. In addition, FIG. 6 shows by arrows a current that flows through the drift region 31 of the MOSFET 900 when a voltage that is positive with respect to the drain electrode 15 is applied to the source electrode 12 of the MOSFET 900.

As shown in FIG. 6, in the element region 101, a forward current flows through the SBD including the first contact portion 12x of the source electrode 12 and the second portion 31y of the drift region 31. The forward current passes between the base regions 33 and flows around the bottom portion of the base region 33. Due to the forward current flowing around the bottom portion of the base region 33, a voltage on the N side of the pn junction diode formed by the base region 33 and the drift region 31 rises, and a voltage applied to the pn junction in the vicinity of the SBD effectively drops. Therefore, the forward voltage (Vf) of the pn junction diode in the element region 101 can be effectively increased. As a result, the flow of the forward current to the pn junction diode in the element region 101 is suppressed.

As shown in FIG. 6, in the termination region 102, a forward current flows through the SBD including the third contact portion 13x of the source electrode wiring layer 13 and the third portion 31z of the drift region 31. The forward current passes between the second p region 37 and the third p region 38 and flows around the bottom portions of the second p region 37, the third p region 38, and the fourth p region 40. However, since there is a distance from the SBD in the termination region 102 to the second p region 37 or the fourth p region 40 close to the element region 101, the flow of current around the bottom portion of the second p region 37 or the fourth p region 40 close to the element region 101 is suppressed.

For this reason, in a portion close to the element region 101, an increase in the voltage on the N side of the pn junction diode formed by the second p region 37 and the drift region 31 or the fourth p region 40 and the drift region 31 is unlikely to occur. That is, a decrease in voltage applied to the pn junction due to the forward current is suppressed. Therefore, the pn junction diode in the termination region 102 close to the element region 101 operates, making it easier for the bipolar current to flow through the drift region 31. As a result, there is a concern that the reliability of the MOSFET 900 may be reduced due to an increase in the on-resistance.

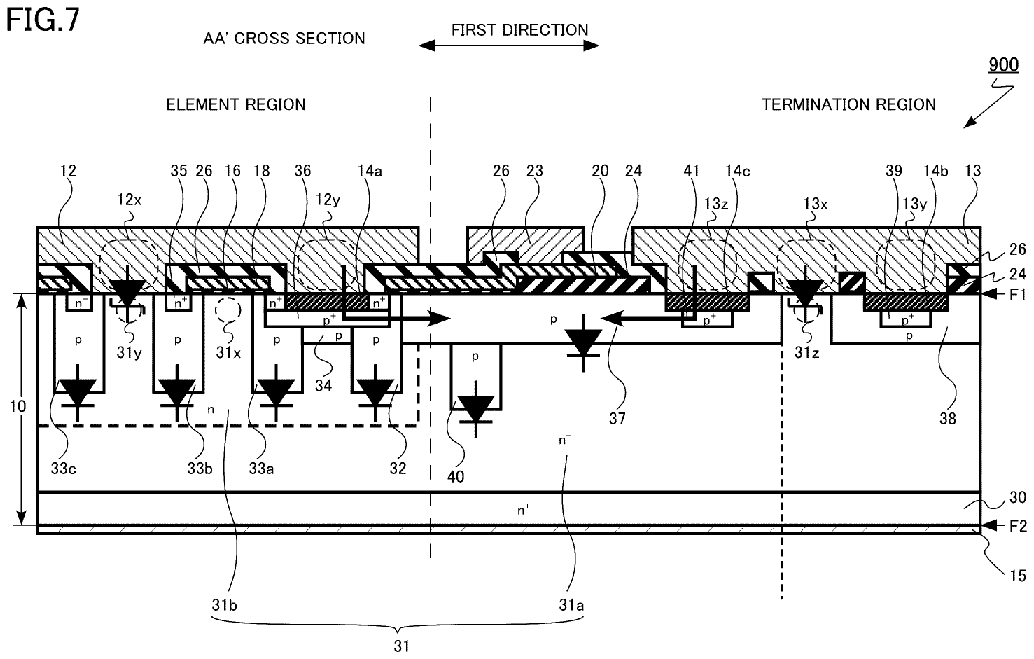

FIG. 7 is an explanatory diagram of a problem of the semiconductor device according to the comparative example. FIG. 7 is a schematic cross-sectional view of the semiconductor device according to the comparative example. FIG. 7 is a diagram corresponding to FIG. 5.

FIG. 7 shows pn junction diodes and SBDs built in the MOSFET 900 using circuit symbols. In addition, FIG. 7 shows by arrows a current that flows into the second p region 37 of p-type of the MOSFET 900 when a voltage that is positive with respect to the drain electrode 15 is applied to the source electrode 12 and the source electrode wiring layer 13 of the MOSFET 900.

In the MOSFET 900 according to the comparative example, the fifth contact portion 13z is in contact with the third silicide layer 14c. The third silicide layer 14c is in contact with the third high concentration p region 41 and the second p region 37.

The contact resistance between the fifth contact portion 13z and the third high concentration p region 41 is reduced by interposing the third silicide layer 14c therebetween. The contact between the fifth contact portion 13z and the third high concentration p region 41 is, for example, an ohmic contact. In addition, the electrical resistance between the fifth contact portion 13z and the second p region 37 is also reduced by interposing the third silicide layer 14c and the third high concentration p region 41 therebetween. Therefore, for example, the contact between the fifth contact portion 13z and the second p region 37 is an ohmic contact.

As shown by the arrow, a current flows into the second p region 37 from the source electrode 12 through the second contact portion 12y. In other words, holes are supplied from the source electrode 12 to the second p region 37 through the second contact portion 12y.

In addition, as shown by the arrow, a current flows into the second p region 37 from the source electrode wiring layer 13 through the fifth contact portion 13z. In other words, holes are supplied from the source electrode wiring layer 13 to the second p region 37 through the fifth contact portion 13z.

An increase in the amount of holes supplied to the second p region 37 promotes the start of the operation of the pn junction diode in the termination region 102 close to the element region 101. In addition, when the pn junction diode operates, the bipolar current flowing through the drift region 31 increases. As a result, there is a concern that the reliability of the MOSFET 900 may be reduced due to an increase in the on-resistance.

Also in the MOSFET 100 according to the first embodiment, as in the MOSFET 900, the pn junction diode in the termination region 102 close to the element region 101 operates, making it easier for the bipolar current to flow through the drift region 31. As a result, there is a concern that the reliability of the MOSFET 100 may be reduced due to an increase in the on-resistance.

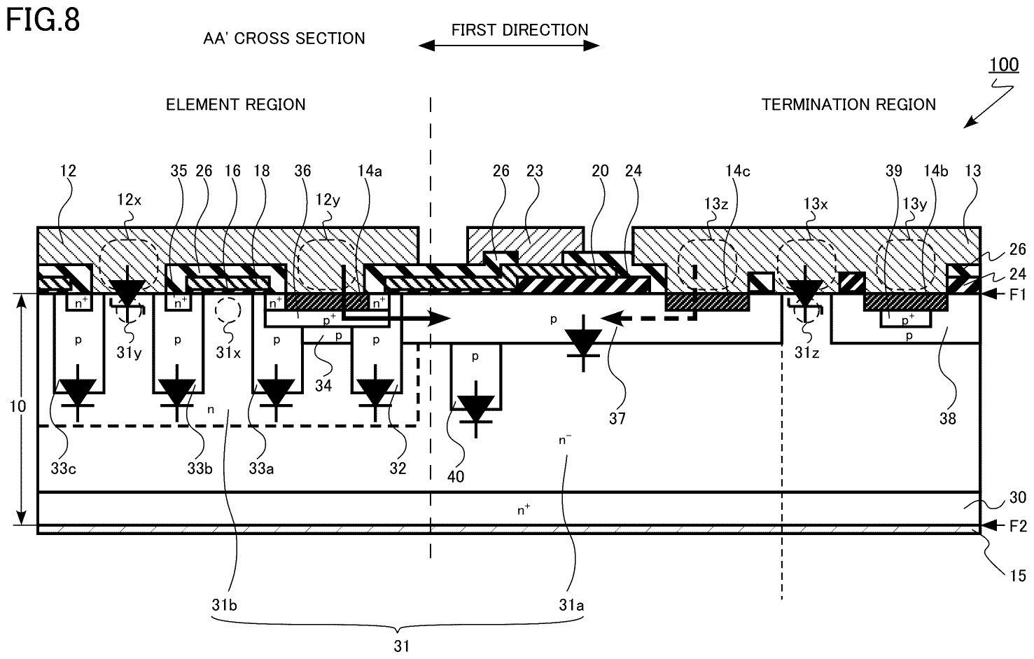

FIG. 8 is an explanatory diagram of the function and effect of the semiconductor device according to the first embodiment. FIG. 8 is a schematic cross-sectional view of the semiconductor device according to the first embodiment. FIG. 8 is a diagram corresponding to FIG. 3. In addition, FIG. 8 is a diagram corresponding to FIG. 7 in the comparative example.

FIG. 8 shows pn junction diodes and SBDs built in the MOSFET 100 using circuit symbols. In addition, FIG. 8 shows by arrows a current that flows into the second p region 37 of p-type of the MOSFET 100 when a voltage that is positive with respect to the drain electrode 15 is applied to the source electrode 12 of the MOSFET 100.

In the MOSFET 100 according to the first embodiment, unlike the MOSFET 900 according to the comparative example, no p-type high concentration region is provided below the third silicide layer 14c. In the MOSFET 100, the third silicide layer 14c is in contact with only the second p region 37.

Compared with the MOSFET 900, the concentration of p-type impurities in the p region in contact with the third silicide layer 14c is low, so that the electrical resistance between the fifth contact portion 13z and the second p region 37 increases.

Therefore, the current that is indicated by the dotted arrow and flows into the second p region 37 from the source electrode wiring layer 13 through the fifth contact portion 13z is smaller than that in the MOSFET 900. The amount of holes supplied from the source electrode wiring layer 13 to the second p region 37 through the fifth contact portion 13z decreases.

Therefore, the start of the operation of the pn junction diode in the termination region 102 close to the element region 101 is suppressed. In addition, when the pn junction diode operates, the bipolar current flowing through the drift region 31 decreases. As a result, the growth of stacking fault is suppressed and the increase in the on-resistance is suppressed, improving the reliability of the MOSFET 100.

From the viewpoint of increasing the contact resistance between the fifth contact portion 13z and the second p region 37, the p-type impurity concentration in a portion of the second p region 37 in contact with the third silicide layer 14c is preferably equal to or less than 1/10, more preferably equal to or less than 1/100 of the p-type impurity concentration in a portion of the second high concentration p region 39 in contact with the second silicide layer 14b.

As described above, according to the first embodiment, a MOSFET is realized in which the flow of a forward current to a pn junction diode is suppressed to improve the reliability.

### Second Embodiment

A semiconductor device according to a second embodiment is different from the semiconductor device according to the first embodiment in that the wiring layer does not include any portion that is in contact with the ninth silicon carbide region directly or with a silicide layer interposed therebetween, other than the third contact portion. Hereinafter, the description of a part of the content overlapping the first embodiment may be omitted.

The semiconductor device according to the second embodiment is a planar gate vertical MOSFET 200 using silicon carbide.

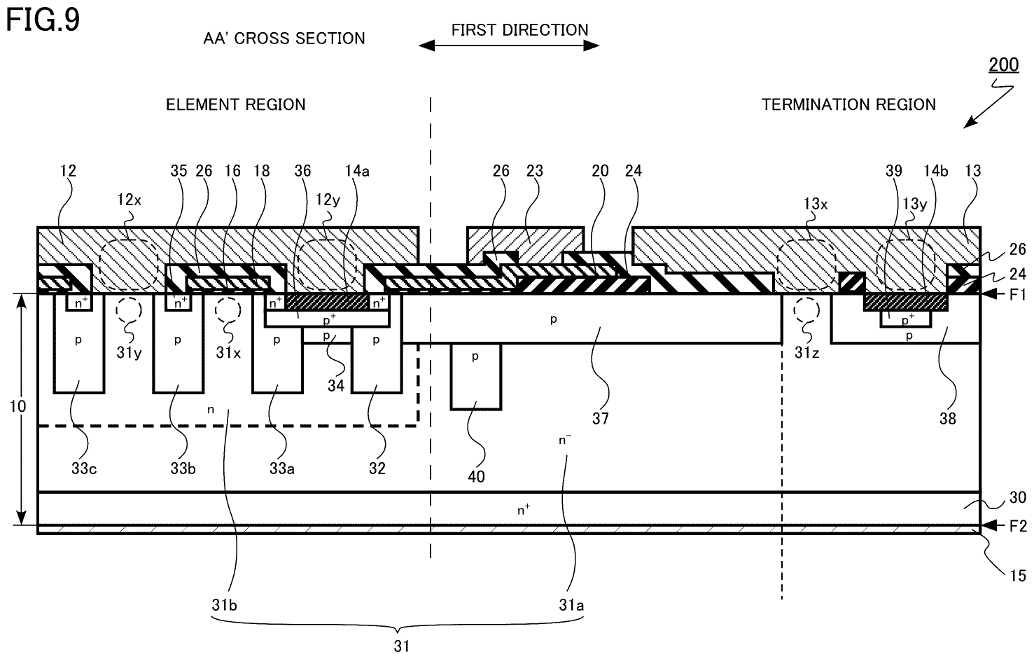

FIG. 9 is a schematic cross-sectional view of the semiconductor device according to the second embodiment. FIG. 9 is a diagram corresponding to FIG. 3 in the first embodiment.

As shown in FIG. 9, a source electrode wiring layer 13 of a MOSFET 200 does not include any portion that is in contact with the second p region 37 directly or with a silicide layer interposed therebetween, other than the third contact portion 13x.

The source electrode wiring layer 13 of the MOSFET 200 does not have the fifth contact portion 13z that the MOSFET 900 according to the comparative example shown in FIG. 5 has. For this reason, when a voltage that is positive with respect to the drain electrode 15 is applied to the source electrode 12 and the source electrode wiring layer 13, a current only flows into the second p region 37 from the source electrode 12 through the second contact portion 12y.

Therefore, compared with the MOSFET 900, the current flowing into the second p region 37 decreases. As a result, the growth of stacking fault is suppressed and the increase in the on-resistance is suppressed, improving the reliability of the MOSFET 200.

### Modification Examples

A semiconductor device according to a modification example of the second embodiment is different from the semiconductor device according to the second embodiment in that the silicon carbide layer in the termination region further includes a thirteenth silicon carbide region of a second conductive type that is provided between the ninth silicon carbide region and the first face and has a higher second conductive type impurity concentration than the ninth silicon carbide region and the tenth silicon carbide region and the third contact portion is in contact with the thirteenth silicon carbide region.

The semiconductor device according to the modification example of the second embodiment is a planar gate vertical MOSFET 201 using silicon carbide.

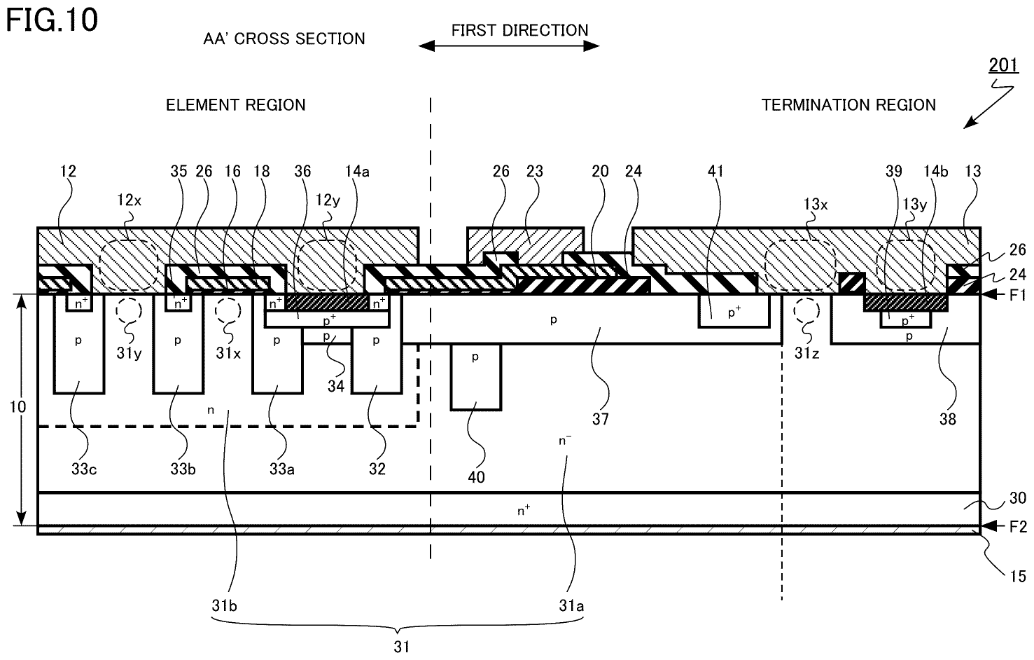

FIG. 10 is a schematic cross-sectional view of the semiconductor device according to the modification example of the second embodiment. FIG. 10 is a diagram corresponding to FIG. 9 in the second embodiment.

As shown in FIG. 10, similarly to the MOSFET 200 according to the second embodiment, the source electrode wiring layer 13 does not include any portion that is in contact with the second p region 37 directly or with a silicide layer interposed therebetween, other than the third contact portion 13x. Therefore, the reliability of a MOSFET 201 is improved.

As shown in FIG. 10, in the MOSFET 201, the third high concentration p region 41 of p⁺-type (thirteenth silicon carbide region) having a higher p-type impurity concentration than the second p region 37 and the third p region 38 is provided between the second p region 37 and the first face F1.

A part of the third contact portion 13x is in contact with the third high concentration p region 41. Since the third contact portion 13x is in contact with the third high concentration p region 41, the contact resistance between the source electrode wiring layer 13 and the second p region 37 is smaller than that in the MOSFET 200.

The electrical resistance between the third contact portion 13x and the second p region 37 of the MOSFET 201 is higher than the electrical resistance between the fourth contact portion 13y and the third p region 38.

In the MOSFET 201, the degree to which the electric potential of the second p region 37 is fixed to the electric potential of the source electrode wiring layer 13 is stronger than in the MOSFET 200. Therefore, compared with the MOSFET 200, for example, the dielectric breakdown voltage of the MOSFET 201 is more stable.

As described above, according to the second embodiment and its modification example, the flow of a forward current to the pn junction diode is suppressed to realize a MOSFET with improved reliability.

### Third Embodiment

A semiconductor device according to a third embodiment is different from the semiconductor device according to the first embodiment in that the wiring layer further includes a fifth contact portion in contact with the ninth silicon carbide region. Hereinafter, the description of a part of the content overlapping the first embodiment may be omitted.

The semiconductor device according to the third embodiment is a planar gate vertical MOSFET 300 using silicon carbide.

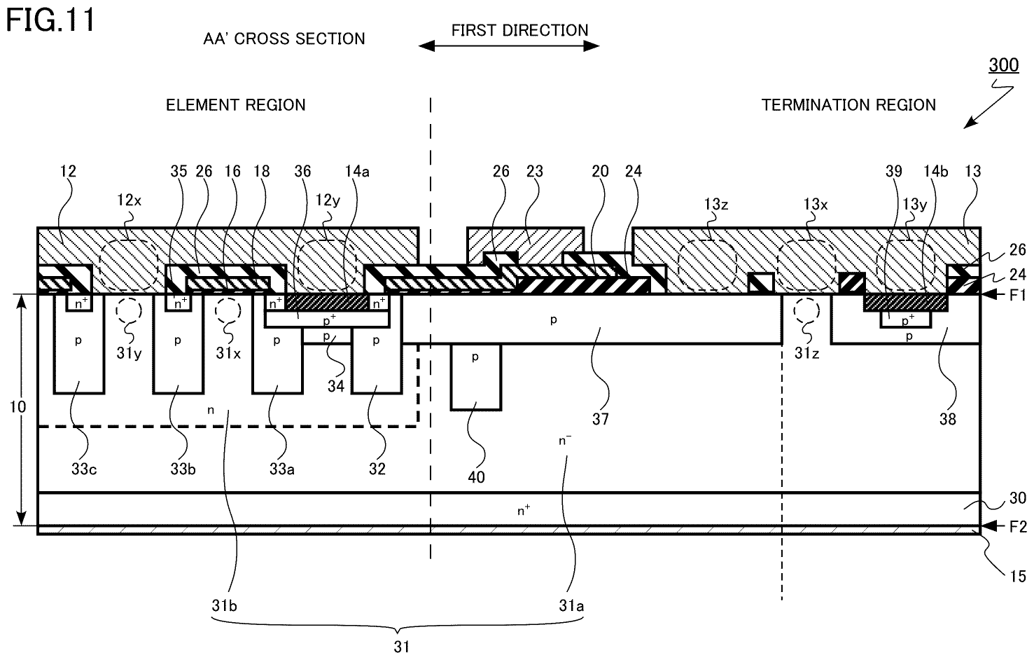

FIG. 11 is a schematic cross-sectional view of the semiconductor device according to the third embodiment. FIG. 11 is a diagram corresponding to FIG. 3 in the first embodiment.

As shown in FIG. 11, a fifth contact portion 13z of a MOSFET 300 is in direct contact with the second p region 37. The fifth contact portion 13z is not in contact with the drift region 31.

Compared with the MOSFET 900 according to the comparative example, the third silicide layer 14c and the third high concentration p region 41 of p⁺-type (thirteenth silicon carbide region) are not provided between the fifth contact portion 13z and the second p region 37 of the MOSFET 300. For this reason, the electrical resistance between the fifth contact portion 13z and the second p region 37 of the MOSFET 300 is higher than the electrical resistance between the fifth contact portion 13z and the second p region 37 of the MOSFET 900.

For example, the electrical resistance between the fifth contact portion 13z and the second p region 37 of the MOSFET 300 is higher than the electrical resistance between the fourth contact portion 13y and the third p region 38.

In the MOSFET 300, when a voltage that is positive with respect to the drain electrode 15 is applied to the source electrode 12 and the source electrode wiring layer 13, the current flowing into the second p region 37 is smaller than that in the MOSFET 900. As a result, the growth of stacking fault is suppressed and the increase in the on-resistance is suppressed, improving the reliability of the MOSFET 300.

As described above, according to the third embodiment, a MOSFET is realized in which the flow of a forward current to a pn junction diode is suppressed to improve the reliability.

### Fourth Embodiment

A semiconductor device according to a fourth embodiment is different from the semiconductor device according to the first embodiment in that the silicon carbide layer in the termination region further includes a thirteenth silicon carbide region of the second conductive type that is provided between the ninth silicon carbide region and the first face and has a higher second conductive type impurity concentration than the ninth silicon carbide region and the tenth silicon carbide region and the wiring layer further includes a fifth contact portion in contact with the thirteenth silicon carbide region. Hereinafter, the description of a part of the content overlapping the first embodiment may be omitted.

The semiconductor device according to the fourth embodiment is a planar gate vertical MOSFET 400 using silicon carbide.

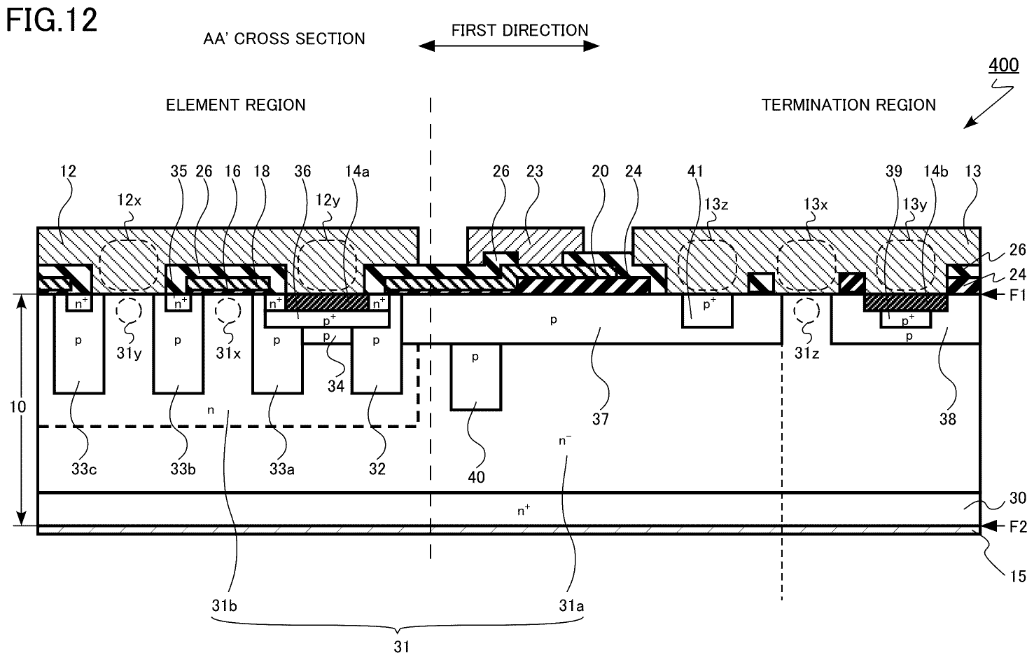

FIG. 12 is a schematic cross-sectional view of the semiconductor device according to the fourth embodiment. FIG. 12 is a diagram corresponding to FIG. 3 in the first embodiment.

As shown in FIG. 12, the third high concentration p region 41 of p⁺-type (thirteenth silicon carbide region) is provided between the first face F1 and the second p region 37 of p-type. The p-type impurity concentration in the third high concentration p region 41 is higher than the p-type impurity concentration in the second p region 37 and the p-type impurity concentration in the third p region 38. The fifth contact portion 13z of the MOSFET 400 is in direct contact with the third high concentration p region 41.

Compared with the MOSFET 900 according to the comparative example, the third silicide layer 14c is not provided between the fifth contact portion 13z and the second p region 37 of the MOSFET 400. For this reason, the electrical resistance between the fifth contact portion 13z and the second p region 37 of the MOSFET 400 is higher than the electrical resistance between the fifth contact portion 13z and the second p region 37 of the MOSFET 900.

For example, the electrical resistance between the fifth contact portion 13z and the second p region 37 of the MOSFET 400 is higher than the electrical resistance between the fourth contact portion 13y and the third p region 38.

In the MOSFET 400, when a voltage that is positive with respect to the drain electrode 15 is applied to the source electrode 12 and the source electrode wiring layer 13, the current flowing into the second p region 37 is smaller than that in the MOSFET 900. As a result, the growth of stacking fault is suppressed and the increase in the on-resistance is suppressed, improving the reliability of the MOSFET 400.

As described above, according to the fourth embodiment, a MOSFET is realized in which the flow of a forward current to a pn junction diode is suppressed to improve the reliability.

### Fifth Embodiment

A semiconductor device according to a fifth embodiment is different from the semiconductor device according to the first embodiment in that the silicon carbide layer in the termination region further includes a thirteenth silicon carbide region of a second conductive type that is provided between the ninth silicon carbide region and the first face and has a higher second conductive type impurity concentration than the ninth silicon carbide region and the tenth silicon carbide region and the ninth silicon carbide region includes a first region in contact with the third silicon carbide region and a second region that surrounds the first region, is spaced apart from the first region, and is in contact with the thirteenth silicon carbide region. Hereinafter, the description of a part of the content overlapping the first embodiment may be omitted.

The semiconductor device according to the fifth embodiment is a planar gate vertical MOSFET 500 using silicon carbide.

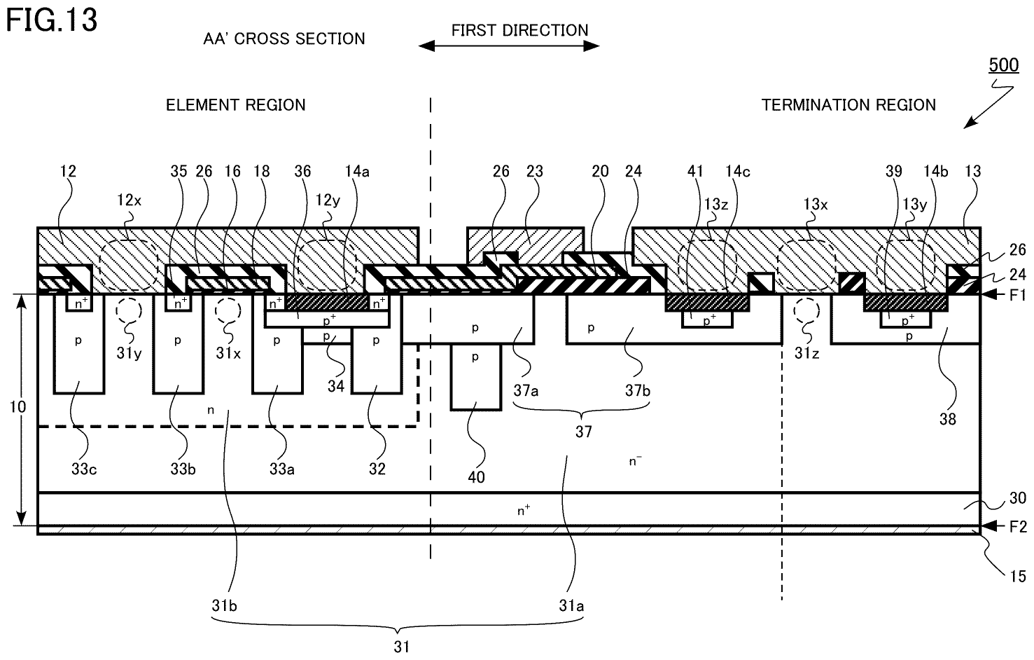

FIG. 13 is a schematic cross-sectional view of the semiconductor device according to the fifth embodiment. FIG. 13 is a diagram corresponding to FIG. 3 in the first embodiment.

As shown in FIG. 13, in a MOSFET 500, a third high concentration p region 41 of p⁺-type (thirteenth silicon carbide region) is provided between the third silicide layer 14c and the second p region 37 of p-type. The p-type impurity concentration in the third high concentration p region 41 is higher than the p-type impurity concentration in the second p region 37 and the p-type impurity concentration in the third p region 38.

For example, the electrical resistance between the fifth contact portion 13z and the second p region 37 of the MOSFET 500 is substantially the same as the electrical resistance between the fourth contact portion 13y and the third p region 38.

In addition, in the MOSFET 500, the second p region 37 of p-type includes an inner region 37a (first region) and an outer region 37b (second region). The second p region 37 is divided into the inner region 37a and the outer region 37b.

The inner region 37a surrounds the element region 101. The inner region 37a is in contact with the outer peripheral p region 32.

The outer region 37b surrounds the inner region 37a. The outer region 37b is spaced apart from the inner region 37a. Between the inner region 37a and the outer region 37b, the drift region 31 is provided. The outer region 37b is in contact with the third high concentration p region 41.

The end of the inner region 37a on the outer region 37b side is provided, for example, closer to a side opposite to the element region 101 than the end of the field insulating layer 24 in the termination region 102 on the element region 101 side. In other words, the end of the inner region 37a on the outer region 37b side is provided, for example, closer to the third p region 38 than the end of the field insulating layer 24 in the termination region 102 on the element region 101 side.

The first distance between the inner region 37a and the outer region 37b in the first direction parallel to the first face is, for example, equal to or more than 0.5 times and equal to or less than 3 times the second distance in the first direction between the base regions 33 adjacent to each other in the first direction. The first distance is, for example, equal to or more than 0.5 times and equal to or less than 3 times the second distance in the first direction between the first base region 33a and the second base region 33b.

The fourth p region 40 of p-type is provided between the drift region 31 and the inner region 37a. The fourth p region 40 is in contact with the inner region 37a.

The MOSFET 500 is different from the MOSFET 900 according to the comparative example in that the second p region 37 is divided into the inner region 37a and the outer region 37b. For this reason, the current flowing into the source electrode 12 and the source electrode wiring layer 13, for example, from the second contact portion 12y of the MOSFET 500 to the outer region 37b is blocked. In addition, the current flowing into the source electrode 12 and the source electrode wiring layer 13, for example, from the fifth contact portion 13z of the MOSFET 500 to the inner region 37a is blocked.

Therefore, compared with the MOSFET 900, the current flowing into the source electrode 12 and the source electrode wiring layer 13 and into the second p region 37 decreases. As a result, the growth of stacking fault is suppressed and the increase in the on-resistance is suppressed, improving the reliability of the MOSFET 500.

From the viewpoint of reducing the current flowing into the second p region 37, the first distance is preferably equal to or more than 0.5 times, more preferably equal to or more than 1 time the second distance.

In addition, from the viewpoint of suppressing breakdown during dynamic operation of the MOSFET 500, it is preferable that the end of the inner region 37a on the outer region 37b side is provided, for example, closer to the side opposite to the element region 101 than the end of the field insulating layer 24 in the termination region 102 on the element region 101 side.

As described above, according to the fifth embodiment, the flow of a forward current to the pn junction diode is suppressed to realize a MOSFET with improved reliability.

In the first to fifth embodiments, the case of 4H-SiC has been described as an example of the crystal structure of SiC. However, embodiments can also be applied to devices using SiC having other crystal structures, such as 6H-SiC and 3C-SiC. In addition, a face other than the (0001) face can also be applied as the surface of the silicon carbide layer 10.

In the first to fifth embodiments, the case where the first conductive type is n-type and the second conductive type is p-type has been described as an example. However, the first conductive type can be p-type and the second conductive type can be n-type.

In the first to fifth embodiments, aluminum (Al) is exemplified as a p-type impurity, but boron (B) can also be used. In addition, although nitrogen (N) and phosphorus (P) are exemplified as n-type impurities, arsenic (As), antimony (Sb), and the like can also be applied.

In the first to fifth embodiments, the case where the gate electrode 18 in the element region 101 has a striped shape has been described as an example. However, for example, the gate electrode 18 may have a mesh-shaped structure.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
an element region; and
a termination region surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first portion in contact with the first face and facing the gate electrode and a second portion in contact with the first face and in contact with the first electrode;
a second silicon carbide region of a second conductive type provided between the first silicon carbide region and the first face;
a third silicon carbide region of the second conductive type provided between the first silicon carbide region and the first face, provided closer to the termination region than the second silicon carbide region, and electrically connected to the first electrode;
a fourth silicon carbide region of the second conductive type provided between the first silicon carbide region and the first face, provided between the second silicon carbide region and the third silicon carbide region, facing the gate electrode, and electrically connected to the first electrode;
a fifth silicon carbide region of the second conductive type provided between the first silicon carbide region and the first face, provided between the second silicon carbide region and the fourth silicon carbide region, facing the gate electrode, and electrically connected to the first electrode;
a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region;
a seventh silicon carbide region of the first conductive type provided between the fifth silicon carbide region and the first face and electrically connected to the first electrode; and
an eighth silicon carbide region of the second conductive type provided between the sixth silicon carbide region and the first face and having a higher second conductive type impurity concentration than the sixth silicon carbide region;
a first silicide layer provided between the eighth silicon carbide region and the first electrode; and
a gate insulating layer provided between the gate electrode and the fifth silicon carbide region and between the gate electrode and the first portion,
the termination region includes:
a wiring layer electrically connected to the first electrode;
the second electrode;
the silicon carbide layer including:
the first silicon carbide region having a third portion in contact with the first face and in contact with the wiring layer;
a ninth silicon carbide region of the second conductive type provided between the first silicon carbide region and the first face, surrounding the element region, and in contact with the third silicon carbide region;
a tenth silicon carbide region of the second conductive type provided between the first silicon carbide region and the first face, surrounding the ninth silicon carbide region, spaced apart from the ninth silicon carbide region, and electrically connected to the wiring layer; and
an eleventh silicon carbide region of the second conductive type provided between the tenth silicon carbide region and the first face and having a higher second conductive type impurity concentration than the ninth silicon carbide region and the tenth silicon carbide region; and
a second silicide layer provided between the eleventh silicon carbide region and the wiring layer,
the first electrode includes a first contact portion in contact with the second portion and a second contact portion in contact with the first silicide layer,
the wiring layer includes a third contact portion in contact with the third portion and a fourth contact portion in contact with the second silicide layer,
the termination region further includes a third silicide layer provided between the ninth silicon carbide region and the first face and in contact with the ninth silicon carbide region, and
the wiring layer further includes a fifth contact portion in contact with the third silicide layer.

2. The semiconductor device according to claim 1,
wherein a second conductive type impurity concentration in a portion of the ninth silicon carbide region in contact with the third silicide layer is equal to or less than 1/10 of a second conductive type impurity concentration in a portion of the eleventh silicon carbide region in contact with the second silicide layer.

3. The semiconductor device according to claim 1,
wherein an electrical resistance between the fifth contact portion and the ninth silicon carbide region is higher than an electrical resistance between the fourth contact portion and the tenth silicon carbide region.

4. The semiconductor device according to claim 1,
wherein the first silicon carbide region of the element region has a low concentration region and a high concentration region provided between the low concentration region and the first face and having a higher first conductive type impurity concentration than the low concentration region, and
the second silicon carbide region, the third silicon carbide region, the fourth silicon carbide region, and the fifth silicon carbide region are provided between the high concentration region and the first face.

5. The semiconductor device according to claim 1,
wherein the silicon carbide layer in the termination region further includes a twelfth silicon carbide region of the second conductive type provided between the first silicon carbide region and the ninth silicon carbide region and spaced apart from the third silicon carbide region in a first direction parallel to the first face.

6. A semiconductor device, comprising:
an element region; and
a termination region surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first portion in contact with the first face and facing the gate electrode and a second portion in contact with the first face and in contact with the first electrode;
a second silicon carbide region of a second conductive type provided between the first silicon carbide region and the first face;
a third silicon carbide region of the second conductive type provided between the first silicon carbide region and the first face, provided on the termination region side of the second silicon carbide region, and electrically connected to the first electrode;
a fourth silicon carbide region of the second conductive type provided between the first silicon carbide region and the first face, provided between the second silicon carbide region and the third silicon carbide region, facing the gate electrode, and electrically connected to the first electrode;
a fifth silicon carbide region of the second conductive type provided between the first silicon carbide region and the first face, provided between the second silicon carbide region and the fourth silicon carbide region, facing the gate electrode, and electrically connected to the first electrode;
a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region;
a seventh silicon carbide region of the first conductive type provided between the fifth silicon carbide region and the first face and electrically connected to the first electrode; and
an eighth silicon carbide region of the second conductive type provided between the sixth silicon carbide region and the first face and having a higher second conductive type impurity concentration than the sixth silicon carbide region;
a first silicide layer provided between the eighth silicon carbide region and the first electrode; and
a gate insulating layer provided between the gate electrode and the fifth silicon carbide region and between the gate electrode and the first portion,
the termination region includes:
a wiring layer electrically connected to the first electrode;
the second electrode;
the silicon carbide layer including:
the first silicon carbide region having a third portion in contact with the first face and in contact with the wiring layer;
a ninth silicon carbide region of the second conductive type provided between the first silicon carbide region and the first face, surrounding the element region, and in contact with the third silicon carbide region;
a tenth silicon carbide region of the second conductive type provided between the first silicon carbide region and the first face, surrounding the ninth silicon carbide region, spaced apart from the ninth silicon carbide region, and electrically connected to the wiring layer; and
an eleventh silicon carbide region of the second conductive type provided between the tenth silicon carbide region and the first face and having a higher second conductive type impurity concentration than the ninth silicon carbide region and the tenth silicon carbide region; and
a second silicide layer provided between the eleventh silicon carbide region and the wiring layer,
the first electrode includes a first contact portion in contact with the second portion and a second contact portion in contact with the first silicide layer,
the wiring layer includes a third contact portion in contact with the third portion and a fourth contact portion in contact with the second silicide layer, and
the wiring layer does not include a portion in contact with the ninth silicon carbide region directly or with a silicide layer interposed therebetween, other than the third contact portion.

7. The semiconductor device according to claim 6,
wherein the silicon carbide layer in the termination region further includes a thirteenth silicon carbide region of the second conductive type provided between the ninth silicon carbide region and the first face and having a higher second conductive type impurity concentration than the ninth silicon carbide region and the tenth silicon carbide region, and
the third contact portion is in contact with the thirteenth silicon carbide region.

8. The semiconductor device according to claim 7,
wherein an electrical resistance between the third contact portion and the ninth silicon carbide region is higher than an electrical resistance between the fourth contact portion and the tenth silicon carbide region.

9. The semiconductor device according to claim 6,
wherein the first silicon carbide region of the element region has a low concentration region and a high concentration region provided between the low concentration region and the first face and having a higher first conductive type impurity concentration than the low concentration region, and
the second silicon carbide region, the third silicon carbide region, the fourth silicon carbide region, and the fifth silicon carbide region are provided between the high concentration region and the first face.

10. The semiconductor device according to claim 6,
wherein the silicon carbide layer in the termination region further includes a twelfth silicon carbide region of the second conductive type provided between the first silicon carbide region and the ninth silicon carbide region and spaced apart from the third silicon carbide region in a first direction parallel to the first face.

11. A semiconductor device, comprising:
an element region; and
a termination region surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first portion in contact with the first face and facing the gate electrode and a second portion in contact with the first face and in contact with the first electrode;
a second silicon carbide region of a second conductive type provided between the first silicon carbide region and the first face;
a third silicon carbide region of the second conductive type provided between the first silicon carbide region and the first face, provided on the termination region side of the second silicon carbide region, and electrically connected to the first electrode;
a fourth silicon carbide region of the second conductive type provided between the first silicon carbide region and the first face, provided between the second silicon carbide region and the third silicon carbide region, facing the gate electrode, and electrically connected to the first electrode;
a fifth silicon carbide region of the second conductive type provided between the first silicon carbide region and the first face, provided between the second silicon carbide region and the fourth silicon carbide region, facing the gate electrode, and electrically connected to the first electrode;
a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region;
a seventh silicon carbide region of the first conductive type provided between the fifth silicon carbide region and the first face and electrically connected to the first electrode; and
an eighth silicon carbide region of the second conductive type provided between the sixth silicon carbide region and the first face and having a higher second conductive type impurity concentration than the sixth silicon carbide region;
a first silicide layer provided between the eighth silicon carbide region and the first electrode; and
a gate insulating layer provided between the gate electrode and the fifth silicon carbide region and between the gate electrode and the first portion,
the termination region includes:
a wiring layer electrically connected to the first electrode;
the second electrode;
the silicon carbide layer including:
the first silicon carbide region having a third portion in contact with the first face and in contact with the wiring layer;
a ninth silicon carbide region of the second conductive type provided between the first silicon carbide region and the first face, surrounding the element region, and in contact with the third silicon carbide region;
a tenth silicon carbide region of the second conductive type provided between the first silicon carbide region and the first face, surrounding the ninth silicon carbide region, spaced apart from the ninth silicon carbide region, and electrically connected to the wiring layer; and
an eleventh silicon carbide region of the second conductive type provided between the tenth silicon carbide region and the first face and having a higher second conductive type impurity concentration than the ninth silicon carbide region and the tenth silicon carbide region; and
a second silicide layer provided between the eleventh silicon carbide region and the wiring layer,
the first electrode includes a first contact portion in contact with the second portion and a second contact portion in contact with the first silicide layer,
the wiring layer includes a third contact portion in contact with the third portion and a fourth contact portion in contact with the second silicide layer, and
the wiring layer further includes a fifth contact portion in contact with the ninth silicon carbide region.

12. The semiconductor device according to claim 11,
wherein the fifth contact portion is not in contact with the first silicon carbide region.

13. The semiconductor device according to claim 11,
wherein an electrical resistance between the fifth contact portion and the ninth silicon carbide region is higher than an electrical resistance between the fourth contact portion and the tenth silicon carbide region.

14. The semiconductor device according to claim 11,
wherein the first silicon carbide region of the element region has a low concentration region and a high concentration region provided between the low concentration region and the first face and having a higher first conductive type impurity concentration than the low concentration region, and
the second silicon carbide region, the third silicon carbide region, the fourth silicon carbide region, and the fifth silicon carbide region are provided between the high concentration region and the first face.

15. The semiconductor device according to claim 11,
wherein the silicon carbide layer in the termination region further includes a twelfth silicon carbide region of the second conductive type provided between the first silicon carbide region and the ninth silicon carbide region and spaced apart from the third silicon carbide region in a first direction parallel to the first face.

16. A semiconductor device, comprising:
an element region; and
a termination region surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first portion in contact with the first face and facing the gate electrode and a second portion in contact with the first face and in contact with the first electrode;
a second silicon carbide region of a second conductive type provided between the first silicon carbide region and the first face;
a third silicon carbide region of the second conductive type provided between the first silicon carbide region and the first face, provided on the termination region side of the second silicon carbide region, and electrically connected to the first electrode;
a fourth silicon carbide region of the second conductive type provided between the first silicon carbide region and the first face, provided between the second silicon carbide region and the third silicon carbide region, facing the gate electrode, and electrically connected to the first electrode;
a fifth silicon carbide region of the second conductive type provided between the first silicon carbide region and the first face, provided between the second silicon carbide region and the fourth silicon carbide region, facing the gate electrode, and electrically connected to the first electrode;
a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region;
a seventh silicon carbide region of the first conductive type provided between the fifth silicon carbide region and the first face and electrically connected to the first electrode; and
an eighth silicon carbide region of the second conductive type provided between the sixth silicon carbide region and the first face and having a higher second conductive type impurity concentration than the sixth silicon carbide region;
a first silicide layer provided between the eighth silicon carbide region and the first electrode; and
a gate insulating layer provided between the gate electrode and the fifth silicon carbide region and between the gate electrode and the first portion,
the termination region includes:
a wiring layer electrically connected to the first electrode;
the second electrode;
the silicon carbide layer including:
the first silicon carbide region having a third portion in contact with the first face and in contact with the wiring layer;
a ninth silicon carbide region of the second conductive type provided between the first silicon carbide region and the first face, surrounding the element region, and in contact with the third silicon carbide region;
a tenth silicon carbide region of the second conductive type provided between the first silicon carbide region and the first face, surrounding the ninth silicon carbide region, spaced apart from the ninth silicon carbide region, and electrically connected to the wiring layer; and
an eleventh silicon carbide region of the second conductive type provided between the tenth silicon carbide region and the first face and having a higher second conductive type impurity concentration than the ninth silicon carbide region and the tenth silicon carbide region; and
a second silicide layer provided between the eleventh silicon carbide region and the wiring layer,
the first electrode includes a first contact portion in contact with the second portion and a second contact portion in contact with the first silicide layer,
the wiring layer includes a third contact portion in contact with the third portion and a fourth contact portion in contact with the second silicide layer,
the silicon carbide layer in the termination region further includes a thirteenth silicon carbide region of the second conductive type provided between the ninth silicon carbide region and the first face and having a higher second conductive type impurity concentration than the ninth silicon carbide region and the tenth silicon carbide region, and
the wiring layer further includes a fifth contact portion in contact with the thirteenth silicon carbide region.

17. The semiconductor device according to claim 16,
wherein no silicide layer is provided between the fifth contact portion and the ninth silicon carbide region.

18. The semiconductor device according to claim 16,
wherein an electrical resistance between the fifth contact portion and the ninth silicon carbide region is higher than an electrical resistance between the fourth contact portion and the tenth silicon carbide region.

19. The semiconductor device according to claim 16,
wherein the first silicon carbide region of the element region has a low concentration region and a high concentration region provided between the low concentration region and the first face and having a higher first conductive type impurity concentration than the low concentration region, and
the second silicon carbide region, the third silicon carbide region, the fourth silicon carbide region, and the fifth silicon carbide region are provided between the high concentration region and the first face.

20. The semiconductor device according to claim 16,
wherein the silicon carbide layer in the termination region further includes a twelfth silicon carbide region of the second conductive type provided between the first silicon carbide region and the ninth silicon carbide region and spaced apart from the third silicon carbide region in a first direction parallel to the first face.

21. A semiconductor device, comprising:
an element region; and
a termination region surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first portion in contact with the first face and facing the gate electrode and a second portion in contact with the first face and in contact with the first electrode;
a second silicon carbide region of a second conductive type provided between the first silicon carbide region and the first face;
a third silicon carbide region of the second conductive type provided between the first silicon carbide region and the first face, provided on the termination region side of the second silicon carbide region, and electrically connected to the first electrode;
a fourth silicon carbide region of the second conductive type provided between the first silicon carbide region and the first face, provided between the second silicon carbide region and the third silicon carbide region, facing the gate electrode, and electrically connected to the first electrode;
a fifth silicon carbide region of the second conductive type provided between the first silicon carbide region and the first face, provided between the second silicon carbide region and the fourth silicon carbide region, facing the gate electrode, and electrically connected to the first electrode;
a sixth silicon carbide region of the second conductive type provided between the first silicon carbide region and the first face, provided between the third silicon carbide region and the fourth silicon carbide region, in contact with the third silicon carbide region and the fourth silicon carbide region, and having a depth smaller than a depth of the third silicon carbide region and a depth of the fourth silicon carbide region;
a seventh silicon carbide region of the first conductive type provided between the fifth silicon carbide region and the first face and electrically connected to the first electrode; and
an eighth silicon carbide region of the second conductive type provided between the sixth silicon carbide region and the first face and having a higher second conductive type impurity concentration than the sixth silicon carbide region;
a first silicide layer provided between the eighth silicon carbide region and the first electrode; and
a gate insulating layer provided between the gate electrode and the fifth silicon carbide region and between the gate electrode and the first portion,
the termination region includes:
a wiring layer electrically connected to the first electrode;
the second electrode;
the silicon carbide layer including:
the first silicon carbide region having a third portion in contact with the first face and in contact with the wiring layer;
a ninth silicon carbide region of the second conductive type provided between the first silicon carbide region and the first face, surrounding the element region, and in contact with the third silicon carbide region;
a tenth silicon carbide region of the second conductive type provided between the first silicon carbide region and the first face, surrounding the ninth silicon carbide region, spaced apart from the ninth silicon carbide region, and electrically connected to the wiring layer;
an eleventh silicon carbide region of the second conductive type provided between the tenth silicon carbide region and the first face and having a higher second conductive type impurity concentration than the ninth silicon carbide region and the tenth silicon carbide region; and
a thirteenth silicon carbide region of the second conductive type provided between the ninth silicon carbide region and the first face and having a higher second conductive type impurity concentration than the ninth silicon carbide region and the tenth silicon carbide region;
a second silicide layer provided between the eleventh silicon carbide region and the wiring layer; and
a third silicide layer provided between the thirteenth silicon carbide region and the wiring layer,
the first electrode includes a first contact portion in contact with the second portion and a second contact portion in contact with the first silicide layer,
the wiring layer includes a third contact portion in contact with the third portion, a fourth contact portion in contact with the second silicide layer, and a fifth contact portion in contact with the third silicide layer, and
the ninth silicon carbide region includes a first region in contact with the third silicon carbide region and a second region surrounding the first region, spaced apart from the first region, and in contact with the thirteenth silicon carbide region.

22. The semiconductor device according to claim 21,
wherein the first silicon carbide region is provided between the first region and the second region.

23. The semiconductor device according to claim 21,
wherein a first distance between the first region and the second region in a first direction parallel to the first face is equal to or more than 0.5 times and equal to or less than 3 times a second distance between the fourth silicon carbide region and the fifth silicon carbide region in the first direction.

24. The semiconductor device according to claim 21,
wherein the first silicon carbide region of the element region has a low concentration region and a high concentration region provided between the low concentration region and the first face and having a higher first conductive type impurity concentration than the low concentration region, and
the second silicon carbide region, the third silicon carbide region, the fourth silicon carbide region, and the fifth silicon carbide region are provided between the high concentration region and the first face.

25. The semiconductor device according to claim 21,
wherein the silicon carbide layer in the termination region further includes a twelfth silicon carbide region of the second conductive type provided between the first silicon carbide region and the first silicon carbide region, in contact with the first region, and spaced apart from the third silicon carbide region in a first direction parallel to the first face.
